(19) United States
(12) Patent Application Publication
(10) Pub. No.: US 2026/0271518 A1
(43) Pub. Date: Sep. 10, 2026

(54) DISPLAY SUBSTRATE AND MANUFACTURING METHOD THEREFOR, AND DISPLAY APPARATUS

(71) Applicant: BOE TECHNOLOGY GROUP CO., LTD., Beijing (CN)

(72) Inventors: Wei YANG, Beijing (CN); Ce NING, Beijing (CN); Hehe HU, Beijing (CN); Guangcai YUAN, Beijing (CN)

(73) Assignee: BOE TECHNOLOGY GROUP CO., LTD., Beijing (CN)

(21) Appl. No.: 19/165,807

(22) PCT Filed: Jun. 24, 2024
(86) PCT No.: PCT/CN2024/100890

§ 371 Date: Sep. 16, 2025

(30) Foreign Application Priority Data
Jul. 31, 2023 (CN) 202310956228.7

(51) Int. Cl. H10K 59/121; G09G 3/3233; H10K 59/12

(52) U.S. Cl. CPC H10K 59/1213; G09G 3/3233; H10K 59/1201; G09G 2300/0426; G09G 2300/0819; G09G 2300/0842; G09G 2300/0861

(57) ABSTRACT

A display substrate, a manufacturing method thereof, and a display apparatus are provided. The display substrate includes a sub-pixel including a pixel circuit, the pixel circuit includes a light emitting device and a driving transistor, the pixel circuit further includes a control transistor, a first electrode of which is electrically connected to a gate electrode of the driving transistor; a material of an active layer of the driving transistor is a first semiconductor material and a material of an active layer of the control transistor is a second semiconductor material, the first semiconductor material being different from the second semiconductor material; an electrode where the active layer of the control transistor is located is directly electrically connected to the gate electrode of the driving transistor and the first electrode of the control transistor.

This application claims priority to Chinese Patent Application No. 202310956228.7, filed Jul. 31, 2023, the disclosure of which is incorporated herein by reference in its entirety.

### TECHNICAL FIELD

At least one embodiment of the present disclosure relates to a display substrate, a manufacturing method thereof, and a display apparatus.

### BACKGROUND

LTPO display substrate integrates oxide transistors (Oxide TFT) and low-temperature polysilicon transistors (LTPS TFT). It has the advantage of low-frequency driving and can reduce the power consumption of display products, so it has been increasingly used in organic light-emitting diode (OLED) display substrates, such as flexible active-matrix organic light-emitting diode (AMOLED) display substrates for mobile display products. However, because the LTPO display substrate integrates LTPS TFT and Oxide TFT, the hydrogen-reducing process of Oxide TFT is easily affected by the hydrogen-rich and high-temperature processes of LTPS TFT, which worsens the device stability of Oxide TFT. Moreover, since the LTPO display substrate integrates LTPS TFT and Oxide TFT, the layout of the signal lines in the pixel area is very complex, which will affect the aperture ratio and transmittance of the LTPO display substrate, making the design more difficult.

### SUMMARY

At least one embodiment of the present disclosure provides a display substrate, the display substrate comprising a sub-pixel, wherein the sub-pixel comprises a pixel circuit, the pixel circuit comprises a light-emitting device and a driving transistor, and the driving transistor is configured to control a driving current flowing through the light-emitting device according to a data signal; the pixel circuit further comprises a control transistor, a first electrode of the control transistor is electrically connected to a gate electrode of the driving transistor; a material of an active layer of the driving transistor is a first semiconductor material and a material of an active layer of the control transistor is a second semiconductor material, the first semiconductor material is different from the second semiconductor material; an electrode where the active layer of the control transistor is located is directly electrically connected to the gate electrode of the driving transistor and the first electrode of the control transistor.

For example, in the display substrate provided by at least one embodiment of the present disclosure, the active layer of the driving transistor and the active layer of the control transistor are arranged in different layers, and the gate electrode of the driving transistor is located between the active layer of the driving transistor and the electrode on which the active layer of the control transistor is located.

For example, in the display substrate provided by at least one embodiment of the present disclosure, the display substrate comprises a base substrate, the driving transistor is disposed on a main surface of the base substrate; the active layer of the driving transistor is located on a side of the active layer of the control transistor proximal to the base substrate.

For example, in the display substrate provided by at least one embodiment of the present disclosure, the pixel circuit comprises: a first reset transistor configured to write a first reset signal to the gate electrode of the driving transistor under a control of a first reset control signal; the control transistor comprises the first reset transistor, and an electrode where an active layer of the first reset transistor is located is directly electrically connected to the gate electrode of the driving transistor and a first electrode of the first reset transistor.

For example, in the display substrate provided by at least one embodiment of the present disclosure, the electrode where the active layer of the first reset transistor is located comprises the active layer of the first reset transistor and the first electrode of the first reset transistor, a material of the first electrode of the first reset transistor is a conductorized material of the second semiconductor material, and the active layer of the first reset transistor and the first electrode of the first reset transistor are arranged in a same layer and constitute an integrated structure; the gate electrode of the driving transistor is arranged in a different layer from the electrode where the active layer of the first reset transistor is located, and the first electrode of the first reset transistor is in contact, through a first via hole exposing the gate electrode of the driving transistor, with the gate electrode of the driving transistor to directly electrically connect the gate electrode of the driving transistor and the first electrode of the first reset transistor.

For example, in the display substrate provided by at least one embodiment of the present disclosure, the electrode where the active layer of the first reset transistor is located further comprises a second electrode of the first reset transistor, and a material of the second electrode of the first reset transistor is a conductorized material of the second semiconductor material; the pixel circuit further comprises a first reset signal line disposed in a different layer from the second electrode of the first reset transistor, and the second electrode of the first reset transistor is in contact, through a second via hole exposing the first reset signal line, with the first reset signal line to directly electrically connect the first reset signal line.

For example, in the display substrate provided by at least one embodiment of the present disclosure, the pixel circuit further comprises: a compensation transistor configured to compensate a signal applied to a gate electrode of the driving transistor in response to a compensation scan signal and the data signal; the control transistor further comprises the compensation transistor, and an electrode where an active layer of the compensation transistor is located is directly electrically connected to the gate electrode of the driving transistor and a first electrode of the compensation transistor.

For example, in the display substrate provided by at least one embodiment of the present disclosure, the electrode where the active layer of the compensation transistor is located further comprises the first electrode of the compensation transistor, and materials of the active layer of the compensation transistor and the first electrode of the compensation transistor are both a conductorized material of the second semiconductor material, and the active layer of the compensation transistor and the first electrode of the compensation transistor are arranged in a same layer and constitute an integrated structure; the gate electrode of the driving transistor and the electrode where the active layer of the compensation transistor is located are arranged in different layers, and the first electrode of the compensation transistor is in contact, through a third via hole exposing the gate electrode of the driving transistor, with the gate electrode of the driving transistor to directly electrically connect the gate electrode of the driving transistor and the first electrode of the compensation transistor.

For example, in the display substrate provided by at least one embodiment of the present disclosure, the control transistor comprises a first reset transistor, an electrode where an active layer of the first reset transistor is located comprises the active layer of the first reset transistor and a first electrode of the first reset transistor, a material of the first electrode of the first reset transistor is the conductorized material of the second semiconductor material, the active layer of the first reset transistor and the first electrode of the first reset transistor are arranged in a same layer and constitute an integrated structure; the gate electrode of the driving transistor and the electrode where the active layer of the first reset transistor are located are arranged in different layers, and the first electrode of the first reset transistor is in contact with the gate electrode of the driving transistor through a first via that exposes the gate electrode of the driving transistor to directly electrically connect the gate electrode of the driving transistor and the first electrode of the first reset transistor, the electrode where the active layer of the compensation transistor and the electrode where the active layer of the first reset transistor is located are arranged in a same layer as and constitute an integrated structure, the first electrode of the first reset transistor and the first electrode of the compensation transistor are integrated, and the first via hole and the second via hole are the same via hole; a material of the active layer of the compensation transistor is the second semiconductor material, a material of the first electrode of the compensation transistor is a conductorized material of the second semiconductor material; the first electrode of the compensation transistor, the first electrode of the compensation transistor and the active layer of the compensation transistor are connected in sequence, arranged in a same layer and constitute an integrated structure.

For example, in the display substrate provided by at least one embodiment of the present disclosure, the pixel circuit further comprises a first light emission control transistor configured to enable the driving current to be applied to the light emitting device under a control of a first light emission control signal; a material of an active layer of the first light emission control transistor is the first semiconductor material, and the active layer of the first light emission control transistor is arranged in a different layer from an active layer of the control transistor; the electrode where the active layer of the compensation transistor is located further comprises a connection portion, a material of the connection portion is a conductorized material of the second semiconductor material, and the connection portion and the active layer of the compensation transistor are arranged in a same layer and constitute an integrated structure; the connection portion is in contact with the active layer of the first light emission control transistor through a fourth via hole exposing the active layer of the first light emission control transistor to electrically connect the active layer of the first light emission control transistor, and the connection portion serves as the first electrode of the first light emission control transistor and the second electrode of the compensation transistor.

For example, in the display substrate provided by at least one embodiment of the present disclosure, the active layer of the first emission control transistor and the active layer of the driving transistor are disposed in the same layer, and/or, the gate electrode of the driving transistor and a gate electrode of the first light emission control transistor are disposed in a same layer.

For example, in the display substrate provided by at least one embodiment of the present disclosure, the pixel circuit further comprises a first emission control transistor configured to enable the driving current to be applied to the light emitting device under a control of a first emission control signal; a material of an active layer of the first light emission control transistor is the first semiconductor material, and the active layer of the first light emission control transistor is arranged in a different layer from the active layer of the control transistor; the electrode where the active layer of the control transistor is located is arranged in a different layer from a second electrode of the first light emission control transistor, the electrode where the active layer of the control transistor is located is in contact with the active layer of the first light emission control transistor through a fourth via hole exposing the active layer of the first light emission control transistor, and the second electrode of the first light emission control transistor is in contact with the active layer of the first light emission control transistor through a fifth via hole exposing the active layer of the first light emission control transistor.

For example, in the display substrate provided by at least one embodiment of the present disclosure, the display substrate comprises a base substrate, the driving transistor being disposed on a main surface of the base substrate; the second electrode of the first light emission control transistor is located on a side of the electrode where the active layer of the control transistor is located distal to the base substrate.

For example, in the display substrate provided by at least one embodiment of the present disclosure, the control transistor comprises a first reset transistor, an electrode where an active layer of the first reset transistor is located further comprises a second electrode of the first reset transistor, a material of the second electrode of the first reset transistor is a conductorized material of the second semiconductor material, the pixel circuit further comprises a first reset signal line provided in a different layer from the second electrode of the first reset transistor, and the second electrode of the first reset transistor is electrically connected to the first reset signal line through a second via hole exposing the first reset signal line, the first reset signal line is disposed in a different layer from the second electrode of the first light emission control transistor.

For example, in the display substrate provided by at least one embodiment of the present disclosure, the first reset signal line and the gate electrode of the driving transistor are located between the gate electrode of the driving transistor and the electrode where the active layer of the control transistor is located; the first reset signal line and the gate electrode of the driving transistor are arranged in different layers or in a same layer.

For example, in the display substrate provided by at least one embodiment of the present disclosure, the control transistor is a single-gate type transistor, a gate electrode of the control transistor is located on a side of the active layer of the control transistor distal to the active layer of the driving transistor; or, the control transistor is a double-gate type transistor, a first gate electrode of the control transistor is located on a side of the active layer of the control transistor distal to the active layer of the driving transistor, and a second gate electrode of the control transistor is located between the active layer of the control transistor and the active layer of the driving transistor, and the second gate electrode of the control transistor and the first reset signal line are arranged in a same layer or in different layers.

For example, in the display substrate provided by at least one embodiment of the present disclosure, the second gate electrode of the control transistor and the gate electrode of the driving transistor are arranged in a lateral direction; in a case that the control transistor is a double-gate type transistor, a line width of the second gate electrode of the control transistor in the lateral direction is greater than a line width of the first gate electrode of the control transistor in the lateral direction.

For example, in the display substrate provided by at least one embodiment of the present disclosure, the display substrate comprises a base substrate, the driving transistor is disposed on a main surface of the base substrate; the first reset signal line and a gate electrode of the control transistor do not overlap in a direction perpendicular to the main surface of the base substrate.

For example, in the display substrate provided by at least one embodiment of the present disclosure, the pixel circuit further comprises a first light emission control transistor configured to enable the driving current to be applied to the light emitting device under a control of a first light emission control signal; a material of an active layer of the first light emission control transistor is the first semiconductor material, and the active layer of the first light emission control transistor is arranged in a different layer from the active layer of the control transistor; the electrode where the active layer of the compensation transistor is located further comprises a second electrode of the compensation transistor, a material of the second electrode of the compensation transistor is a conductorized material of the second semiconductor material, and the second electrode of the compensation transistor and the active layer of the compensation transistor are arranged in a same layer and constitute an integrated structure; the pixel circuit comprises a first connection structure, and the first connection structure, the second electrode of the compensation transistor, and the electrode where the active layer of the control transistor are all arranged in different layers from each other; the first connection structure is electrically connected to the second electrode of the compensation transistor through a sixth via hole, and is electrically connected to the active layer of the first light emission control transistor through a seventh via hole.

For example, in the display substrate provided by at least one embodiment of the present disclosure, the display substrate comprises a base substrate, the driving transistor is disposed on a main surface of the base substrate; the fifth via hole penetrates the second electrode of the compensation transistor, the first connection structure comprises an in-hole portion located in the sixth via hole, a side surface of the in-hole portion is in contact with the second electrode of the compensation transistor, a surface where the side surface of the in-hole portion is located intersects with a surface where the main surface of the base substrate is located; or, the fifth via exposes an upper surface of the second electrode of the compensation transistor, the upper surface of the second electrode of the compensation transistor is distal to the main surface of the base substrate, and the first connection structure comprises a in-hole portion in the sixth via hole, a bottom surface of the in-hole portion is in contact with the upper surface of the second electrode of the compensation transistor.

For example, in the display substrate provided by at least one embodiment of the present disclosure, the pixel circuit further comprises a first light emission control transistor configured to enable the driving current to be applied to the light emitting device under a control of a first light emission control signal; a material of an active layer of the first light emission control transistor is the first semiconductor material, and the active layer of the first light emission control transistor is arranged in a different layer from the active layer of the control transistor; an electrode where the active layer of the compensation transistor is located further comprises a second electrode of the compensation transistor, a material of the second electrode of the compensation transistor is a conductorized material of the second semiconductor material, and the connection portion and the active layer of the compensation transistor are arranged in a same layer as and constitute an integrated structure; the pixel circuit further comprises a second connection structure and a third connection structure, and the second electrode of the compensation transistor, the second connection structure, the third connection structure and the active layer of the first light emission control transistor are all arranged in different layers from each other; the second electrode of the compensation transistor is electrically connected to the second connection structure through an eighth via hole, the third connection structure is electrically connected to the second connection structure through a ninth via hole, and the third connection structure is electrically connected to the active layer of the first light emission control transistor through a tenth via hole.

For example, in the display substrate provided by at least one embodiment of the present disclosure, the first semiconductor material is a silicon semiconductor material and the second semiconductor material is a transparent metal oxide semiconductor material.

For example, in the display substrate provided by at least one embodiment of the present disclosure, the transparent metal oxide semiconductor material comprises indium gallium zinc oxide (IGZO).

At least one embodiment of the present disclosure further provides a display apparatus, which includes any display substrate provided by the embodiment of the present disclosure.

At least one embodiment of the present disclosure further provides a method for manufacturing a display substrate, comprising: forming a sub-pixel, comprising forming a pixel circuit, wherein the forming a pixel circuit comprises: forming a light emitting device and a driving transistor configured to control a magnitude of a driving current flowing through the light emitting device according to a data signal; the forming a pixel circuit further comprises: forming a control transistor, wherein a first electrode of the control transistor is electrically connected to a gate electrode of the driving transistor; a material of an active layer of the driving transistor is a first semiconductor material and a material of an active layer of the control transistor is a second semiconductor material, the first semiconductor material is different from the second semiconductor material; an electrode where the active layer of the control transistor is located is directly electrically connected to the gate electrode of the driving transistor and the first electrode of the control transistor.

For example, the method for manufacturing the display substrate provided by the at least one embodiment of the present disclosure, comprising: forming a first type of via hole, wherein the first type of via hole at least exposes an active layer of the first semiconductor material; forming a first electrically conductive structure to electrically connect, through the first type of via hole, with a surface of the active layer of the first semiconductor material exposed by the first type of via hole; after forming the first type of via hole, performing a high temperature annealing process on the display substrate; and subjecting a surface of the active layer of the first semiconductor material exposed by the first type of via hole to a contact resistance reduction treatment.

For example, the method for manufacturing the display substrate provided by the at least one embodiment of the present disclosure, comprising: forming a second semiconductor layer by using the second semiconductor material through a single patterning process; conductorizing a portion of the second semiconductor layer to form a second electrically conductive structure, wherein the second electrically conductive structure serves as an electrode where the active layer of the control transistor is located, and comprises a conductorized portion and a non-conductorized portion, and the conductorized portion and the non-conductorized portion constitute an integrated structure; the non-conductorized portion constitutes the active layer of the control transistor, the conductorized portion is directly electrically connected the gate electrode of the driving transistor and the first electrode of the control transistor, and a material of the conductorized portion is the conductorized material of the second semiconductor material; and forming a second type of via hole, the conductorized portion of the second electrically conductive structure is directly electrically connected to the gate electrode of the driving transistor and the first electrode of the control transistor through the second type of via hole.

For example, the method for manufacturing the display substrate provided by the at least one embodiment of the present disclosure, comprising: performing the high temperature annealing process on the display substrate, after forming the second type of via hole and before forming the second electrically conductive structure.

### BRIEF DESCRIPTION OF DRAWINGS

In order to explain the technical solutions of the embodiments of the present invention more clearly, the drawings of the embodiments will be briefly introduced below. Obviously, the drawings in the following description only relate to some embodiments of the present invention and do not limit the present invention.

FIG. 1 is a schematic plan view of a display substrate provided by at least one embodiment of the present disclosure;

FIG. 2 is a schematic diagram of a pixel circuit provided by at least one embodiment of the present disclosure;

FIG. 3 is a partial cross-sectional schematic diagram of a pixel circuit of a display substrate provided by at least one embodiment of the present disclosure;

FIG. 4 is a partial cross-sectional schematic diagram of a pixel circuit;

FIG. 5 is a partial plan view of a pixel circuit;

FIG. 6 is a partial cross-sectional schematic diagram of a pixel circuit of another display substrate provided by at least one embodiment of the present disclosure;

FIG. 7 is a partial cross-sectional schematic diagram of a pixel circuit of yet another display substrate provided by at least one embodiment of the present disclosure;

FIG. 8 is a partial cross-sectional schematic diagram of a pixel circuit of yet another display substrate provided by at least one embodiment of the present disclosure;

FIG. 9 is a partial cross-sectional schematic diagram of a pixel circuit of another display substrate provided by at least one embodiment of the present disclosure;

FIG. 10 is a partial cross-sectional schematic diagram of a pixel circuit of another display substrate provided by at least one embodiment of the present disclosure;

FIG. 11 is a partial cross-sectional schematic diagram of a pixel circuit of another display substrate provided by at least one embodiment of the present disclosure;

FIG. 12 is a partial cross-sectional schematic diagram of a pixel circuit of another display substrate provided by at least one embodiment of the present disclosure;

FIG. 13 is a schematic diagram of a display apparatus provided by an embodiment of the present disclosure;

FIGS. 14A to 14D are schematic diagrams of a method for manufacturing a display substrate provided by an embodiment of the present disclosure;

FIGS. 15A to 15D are schematic diagrams of a method for manufacturing a display substrate provided by an embodiment of the present disclosure;

FIGS. 16A to 16D are schematic diagrams of a method for manufacturing a display substrate provided by an embodiment of the present disclosure;

FIGS. 17A to 17D are schematic diagrams of a method for manufacturing a display substrate provided by an embodiment of the present disclosure.

### DETAILED DESCRIPTION

In order to make the purpose, technical solutions and advantages of the embodiments of the present invention clearer, the technical solutions of the embodiments of the present invention will be clearly and completely described below with reference to the accompanying drawings of the embodiments of the present invention. Obviously, the described embodiments are some, but not all, of the embodiments of the present invention. Based on the described embodiments of the present invention, all other embodiments obtained by those of ordinary skill in the art without creative efforts fall within the scope of protection of the present invention.

Unless otherwise defined, technical or scientific terms used herein shall have their ordinary meaning as commonly understood by one of ordinary skill in the art to which this invention belongs. The terms “first”, “second” and similar words used in the description and claims of this patent application do not indicate any order, quantity or importance, but are only used to distinguish different components. Words such as “include” or “include” mean that the elements or items appearing before the word include the elements or items listed after the word and their equivalents, without excluding other elements or items. “Inner”, “outer”, “upper”, “lower”, etc. are only used to express relative positional relationships. When the absolute position of the described object changes, the relative positional relationship may also change accordingly.

Terms in this disclosure are explained as follows:
(1) Meaning of integrated structure: the description that the A structure and the B structure constitute an integrated structure means that there are no seams between the A structure and the B structure and are a one-piece structure with a uniform texture, for example, formed through the same patterning process. Letters A, B are used to refer to corresponding structures described herein.

(2) Meaning of the same layer arrangement: the relationship between multiple structures obtained from the same patterning process performed on the films made of the same material. “Arranged in the same layer” here does not always mean that the thickness of multiple structures is the same or the height of multiple structures in a cross-sectional view is the same.

(3) The meaning of a single patterning process: patterning a certain film layer through one exposure process using one mask.

The drawings in the present disclosure are not strictly drawn to actual scales, and the number of sub-pixels in the display substrate is not limited to the number shown in the drawings, and the specific size and number of each structure can be determined according to actual needs. The drawings described in this disclosure are only structural schematic diagrams.

At least one embodiment of the present disclosure provides a display substrate, the display substrate comprising a sub-pixel, the sub-pixel comprising a pixel circuit, the pixel circuit comprising a light-emitting device and a driving transistor, the driving transistor being configured to control magnitude of driving current flowing through the light-emitting device according to a data signal; the pixel circuit further comprises a control transistor, a first electrode of the control transistor is electrically connected to a gate electrode of the driving transistor. A material of an active layer of the driving transistor is a first semiconductor material and a material of an active layer of the control transistor is a second semiconductor material, the first semiconductor material being different from the second semiconductor material. An electrode where the active layer of the control transistor is located is directly electrically connected to the gate electrode of the driving transistor and the first electrode of the control transistor.

At least one embodiment of the present disclosure further provides a display apparatus, which includes any one of display substrates provided by the embodiment of the present disclosure.

At least one embodiment of the present disclosure further provides a manufacturing method of a display substrate, the manufacturing method including: forming a sub-pixel, including forming a pixel circuit, wherein the forming the pixel circuit includes: forming a light-emitting device and a driving transistor, and the driving transistor is configured to control magnitude of driving current flowing through the light-emitting device according to a data signal. The forming the pixel circuit further includes: forming a control transistor, a first electrode of the control transistor is electrically connected to a gate electrode of the driving transistor. A material of an active layer of the driving transistor is a first semiconductor material and a material of an active layer of the control transistor is a second semiconductor material, the first semiconductor material being different from the second semiconductor material. An electrode where the active layer of the control transistor is located is directly electrically connected to the gate electrode of the driving transistor and the first electrode of the control transistor.

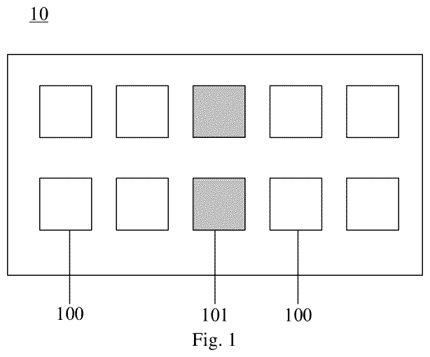

FIG. 1 is a schematic plan view of a display substrate provided by at least one embodiment of the present disclosure. As shown in FIG. 1, for example, the display substrate 10 includes a plurality of pixels 100 arranged in an array, at least some pixels 100 of the plurality of pixels 100 include a plurality of sub-pixels, and at least some sub-pixels of the plurality of sub-pixels include a light-emitting device and a pixel circuit that drives a light-emitting device to emit light. For example, the pixel circuit may include a 2T1C (i.e., two transistors and one capacitor) pixel circuit, a 4T2C, 5T1C, 7T1C or nTmC (n and m are positive integers) pixel circuit. For example, in different embodiments, the pixel circuit may further include a compensation sub-circuit, which includes an internal compensation sub-circuit or an external compensation sub-circuit, and the compensation sub-circuit may include transistors, capacitors, etc. For example, according to the need, the pixel circuit may further include a reset circuit, a light emission control sub-circuit, a detection circuit, etc.

For example, as shown in FIG. 1, a plurality of pixels 100 are located in a display area. For example, in the display substrate 10 provided by some embodiments, some of the pixels in the plurality of pixels 100 are dummy pixels 101, the dummy pixels 101 do not participate in the display work, each dummy pixel 101 includes a plurality of dummy sub-pixels but does not include sub-pixels that has display driving effect.

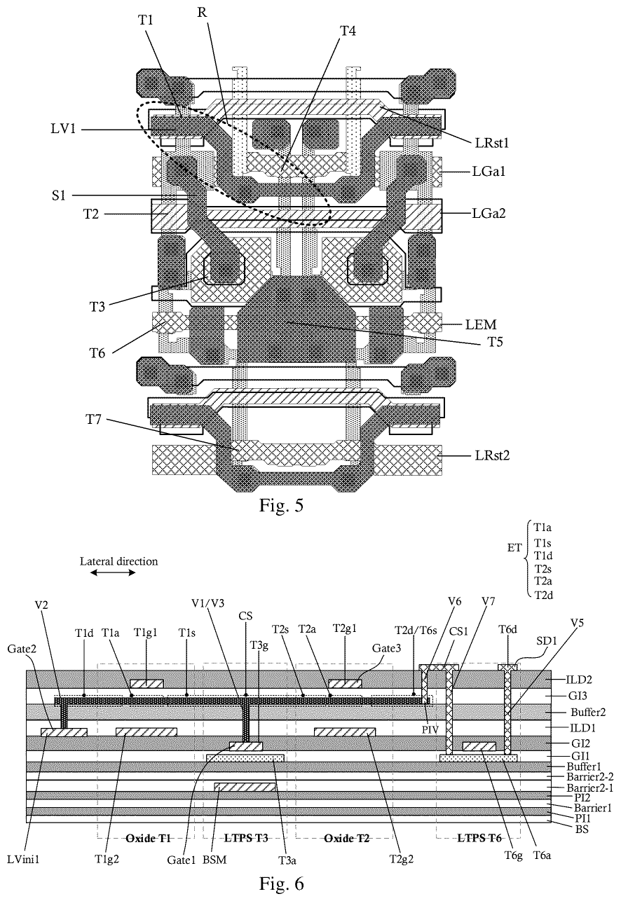

For example, the display substrate 10 is an organic light emitting diode (OLED) display substrate, and the light emitting device is an OLED. The display substrate 10 may further include a plurality of scan lines for providing scan signals (such as gate lines, control signals, refer to FIG. 5) and a plurality of data lines for providing data signals to the plurality of sub-pixels, thereby driving the plurality of sub-pixels. If necessary, the display substrate 10 may further include power lines, detection lines, etc.

The pixel circuit of the display substrate 10 provided by the embodiment of the present disclosure includes a light-emitting device and a driving transistor, and the driving transistor is configured to control magnitude of driving current flowing through the light-emitting device according to the data signal. The pixel circuit further includes a control transistor, a first electrode of the control transistor is electrically connected to a gate electrode of the driving transistor. A material of an active layer of the driving transistor is a first semiconductor material, a material of an active layer of the control transistor is a second semiconductor material, the first semiconductor material being different from the second semiconductor material. An electrode where the active layer of the control transistor is located is directly electrically connected to the gate electrode of the driving transistor and the first electrode of the control transistor, that is, the electrode where the active layer of the control transistor is located serves as a connection line electrically connecting the gate electrode of the driving transistor with the first electrode of the control transistor.

It should be noted that “the electrode where the active layer of the control transistor is located is directly electrically connected to the gate electrode of the driving transistor and the first electrode of the control transistor” mentioned here means that the electrode where the active layer of the control transistor is located is in direct contact with the gate electrode of the driving transistor and the first electrode of the control transistor, in order to electrically connect the gate electrode of the driving transistor with the first electrode of the control transistor, rather than indirectly electrically connecting the first electrode of the active layer of the control transistor with the gate electrode of the driving transistor via other electrically conductive structures (such as electrically conductive structures located in other layers).

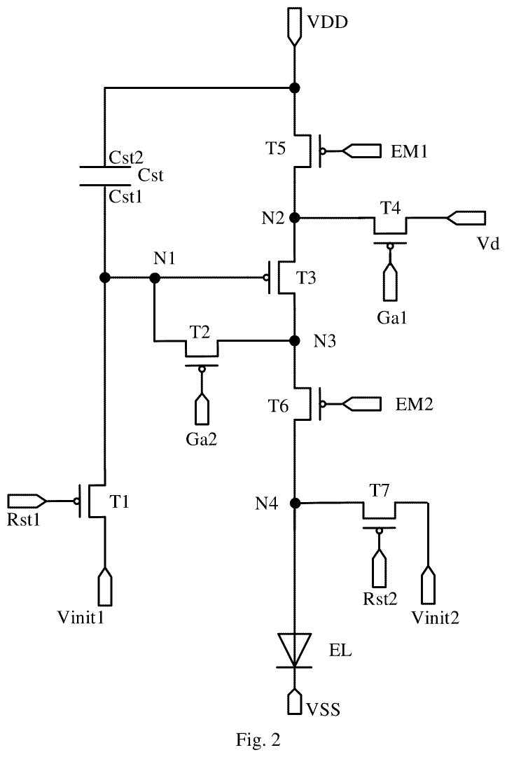

Exemplarily, FIG. 2 is a schematic diagram of a pixel circuit provided by at least one embodiment of the present disclosure. Here, the 7T1C pixel circuit shown in FIG. 2 is used as an example to introduce the structure of the sub-pixel of the display substrate.

Referring to FIG. 2, the pixel circuit includes a light-emitting device EL, and a driving transistor T3 configured to control the magnitude of the driving current flowing through the light-emitting device EL according to a data signal Vd. For example, the pixel circuit includes a first reset transistor T1 configured to write a first reset signal Vinit1 to the gate electrode T3g of the driving transistor T3 under the control of the first reset control signal Rst1. For example, the first reset signal Vinit1 and the second reset signal Vinit2 are the same signal and come from the same reset signal line connected to the same reset signal terminal, which can save a reset signal line. Of course, the first reset signal Vinit1 and the second reset signal Vinit2 may also be two independent signals.

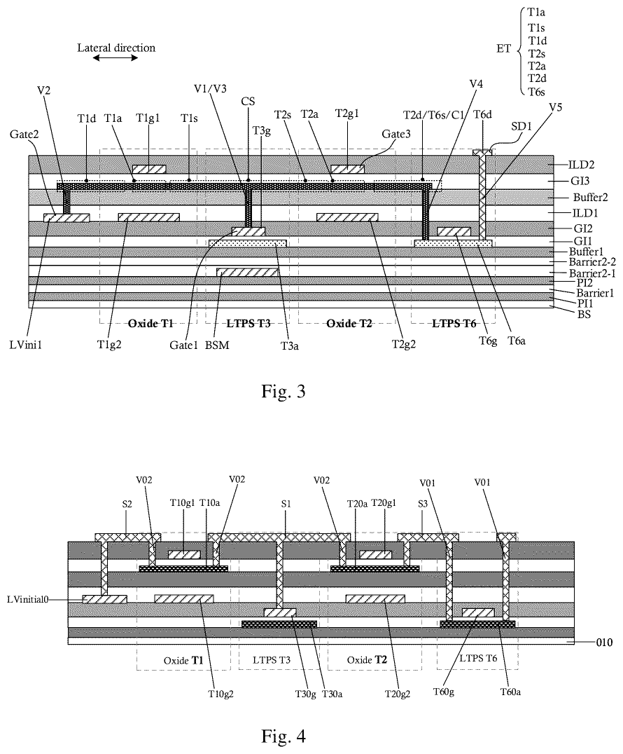

FIG. 3 is a partial cross-sectional schematic diagram of a pixel circuit of a display substrate provided by at least one embodiment of the present disclosure. Referring to FIG. 2 and FIG. 3, for example, the above-mentioned control transistor includes a first reset transistor T1, and the electrode ET where the active layer T1a of the first reset transistor T1 is located is directly electrically connected to the gate electrode T3g of the driving transistor T3 and the first electrode T1s of the first reset transistor T1. The electrode ET where the active layer T1a of the first reset transistor T1 is located is an integrated structure and includes the active layer T1a of the first reset transistor T1 and other parts, that is, the active layer T1a of the first reset transistor T1 and other parts form an integrated electrode ET. In this case, the material of the active layer T3a of the driving transistor T3 is the first semiconductor material, and the material of the active layer T1a of the first reset transistor T1 is the second semiconductor material. The electrode ET where the active layer T1a of the first reset transistor T1 is located further includes a conductorized portion, the conductorized portion and the active layer T1a of the first reset transistor T1 form an integrated structure. The conductorized portion includes the first electrode T1s of the first reset transistor T1, for example, the first electrode T1s of the first reset transistor T1 is adjacent to the active layer T1a of the first reset transistor T1 and forms an integrated structure, and the conductorized portion is in contact with the gate electrode T3g of the driving transistor T3, thereby realizing that the first electrode T1s of the first reset transistor T1 is electrically connected to the active layer T1a of the first reset transistor T1 and to the gate electrode T3g of the driving transistor T3. For example, the material of the conductorized portion is a conductorized second semiconductor material.

FIG. 4 is a partial cross-sectional schematic diagram of a pixel circuit (FIG. 4 does not represent the prior art. FIG. 4 is a design made by the inventor based on the structure of the pixel circuit of the display substrate provided by the embodiment of the present application, but the connection design of the control transistor and other transistors is different from those in the embodiment of the present application). The circuit diagram of the pixel circuit shown in FIG. 4 may be the same as that shown in FIG. 2. However, in the pixel circuit shown in FIG. 4, the first reset transistor T1 includes double gate electrodes T10g1 and T10g2, an active layer T10a, a first electrode and a second electrode. The active layer T10a of the first reset transistor T1 is electrically connected to the gate electrode T30g of the driving transistor T3 through a first connection structure S1, and the first connection structure S1 serves as the first electrode of the first reset transistor T1. The first connection structure S1 is located in different layers from the active layer T10a of the first reset transistor T1 and the gate electrode T30g of the driving transistor T3. For example, the first connection structure S1 is located at a side of both the active layer T10a of the first reset transistor T1 and the gate electrode T30g of the driving transistor T3 facing away from the substrate 010, and the first connection structure S1 is electrically connected to the active layer T10a of the first reset transistor T1 and the gate electrode T30g of the driving transistor T3 through two via holes respectively. For example, the first connection structure S1 is often arranged in the same layer as the data line that provides the data signal. In FIG. 4, the first connection structure S1 is further electrically connected with the gate electrode T30g of the driving transistor T3 and an active layer T20a of a compensation transistor T2 through via holes, and is multi-used as a first electrode of the compensation transistor T2. The compensation transistor T2 includes double gate electrodes T20g1 and T20g2. In FIG. 4, the second electrode of the first reset transistor T1 is electrically connected to the active layer T10a of the first reset transistor T1 and the first reset signal line LVinitial0 by a second connection structure S2 through two via holes respectively. The second connection structure S2 and the first connection structure S1 are arranged in the same layer or in different layers. However, both the second connection structure S2 and the first connection structure S1 are insulated from the active layer T10a of the first reset transistor T1 by an insulating layer provided therebetween; both the second connection structure S2 and the first connection structure S1 are insulated from the first reset signal line LVinitial0 by an insulating layer provided therebetween; both the second connection structure S2 and the first connection structure S1 are insulated from the active layer T20a of the compensation transistor T2 by an insulating layer provided therebetween. Both the second connection structure S2 and the first connection structure S1 are electrically conductive structures which are additionally provided in addition to the layers where the active layer T20a of the compensation transistor T2, the first reset signal line LVinitial0, and the active layer T20a of the compensation transistor T2 are located, so that the electrical connections between the above three elements or the electrical connections between the above three elements and other structures can be achieved through these electrically conductive structures.

In the display substrate provided by the embodiment of the present disclosure, the electrode ET where the active layer T1a of the first reset transistor T1 is located and having a conductorized portion is directly connected to the gate electrode T3g of the driving transistor T3 and the first electrode T1s of the first reset transistor T1. In this way, compared with the structure of the pixel circuit shown in FIG. 4, the display substrate provided by the embodiment of the present disclosure can achieve at least the following technical effects. On the one hand, in the display substrate provided by the embodiment of the present disclosure, the electrode ET where the active layer T1a of the first reset transistor T1 is located is multi-used as a connection electrode to realize the electrical connection between the gate electrode T3g of the driving transistor T3 and the first electrode T1s of the first reset transistor T1, and there is no need to additionally set a special connection electrode in other layers (for example, the electrically conductive layer SD1 at a side of the active layer T1a of the first reset transistor T1 facing away from the base substrate BS) and to enable the connection electrode to electrically connect the gate electrode T3g of the driving transistor T3 and the first electrode T1s of the first reset transistor T1 through at least two via holes respectively, thereby greatly simplifying the structure of the pixel circuit. On the other hand, using the display substrate provided by the embodiments of the present disclosure, other signal lines (such as data lines providing data signals Vd) or connection electrodes for electrical connections between other elements of pixel circuits can be provided in other layers (such as the electrically conductive layer SD1) without the need of providing a connection electrode for connecting the gate electrode T3g of the driving transistor T3 and the first electrode T1s of the first reset transistor T1, thereby reducing the number of electrical conductive structures provided in other layers and reducing the number of connection vias, thereby simplifying the process of fabricating the vias, which is beneficial to reducing design difficulty and improving the yield of the display panel. At the same time, it reduces the density of electrically conductive structures provided in other layers (such as conductive layer SD1), reduces parasitic capacitance caused by excessive density of electrically conductive structures, and improves display quality.

For example, the first semiconductor material is a silicon semiconductor material and the second semiconductor material is a transparent metal oxide semiconductor material. For example, the transparent metal oxide semiconductor material includes indium gallium zinc oxide (IGZO). In this case, the display substrate 10 is an LTPO display substrate integrating oxide transistors (Oxide TFTs) and low-temperature polysilicon transistors (LTPS TFTs), which has the advantage of low-frequency driving and can reduce the power consumption of the display product. Of course, the first semiconductor material and the second semiconductor material are not limited to the types listed above, and the specific types of the first semiconductor material and the second semiconductor material are not limited in the embodiments of the present disclosure.

Referring to FIG. 2 and FIG. 3, for example, the electrode ET where the active layer T1a of the first reset transistor T1 is located includes the first electrode T1s of the first reset transistor T1, and is electrically connected to the gate electrode T3g of the driving transistor T3 through the first via hole V1.

Referring to FIG. 2 and FIG. 3, the electrode ET where the active layer T1a of the first reset transistor T1 is located includes the active layer T1a of the first reset transistor T1 and the first electrode T1s of the first reset transistor T1; and the conductorized portion of the electrode ET where the active layer T1a of the first reset transistor T1 is located includes the first electrode T1s of the first reset transistor T1. For example, the material of the first electrode T1s of the first reset transistor T1 is a conductorized material of the second semiconductor material, and the active layer T1a of the first reset transistor T1 and the first electrode T1s of the first reset transistor T1 are provided in the same layer and formed an integrated structure, that is, the material of the conductorized portion of the electrode ET where the active layer T1a of the first reset transistor T1 is located is a conductorized material of the second semiconductor material, the first electrode T1s of the first reset transistor T1 belongs to the conductorized portion of the electrode ET where the active layer T1a of the first reset transistor T1 is located, and the active layer T1a of the first reset transistor T1 is not conductorized. For example, the gate electrode T3g of the driving transistor T3 is arranged in a different layer from the electrode ET where the active layer T1a of the first reset transistor T1 is located, and the first electrode T1s of the first reset transistor T1 is in contact with the gate electrode T3g of the driving transistor T3 through the first via V1 exposing the gate electrode T3g of the driving transistor T3 to directly electrically connect the gate electrode T3g of the driving transistor T3 and the first electrode T1s of the first reset transistor T1. In this way, for example, the conductorized portion of the electrode ET where the active layer T1a of the first reset transistor T1 is located is electrically connected to the gate electrode T3g of the driving transistor T3 through only the first via hole V1, and the active layer T1a of the first reset transistor T1 and the active layer T1a of the first reset transistor T1 form an integrated structure, thereby realizing the electrical connection between the gate electrode T3g of the driving transistor T3 and the first electrode T1s of the first reset transistor T1, and there is no need to separately set a connection structure as FIG. 3 in other layers to be electrically connected to the gate electrode T3g of the driving transistor T3 and the first electrode T1s of the first reset transistor T1 through at least two via holes, making full use of the electrode EL where the material of the active layer T1a of the first reset transistor T1 is located, simplifying the structure of the sub-pixel, reducing the connection wiring, thereby further increasing the light transmittance. Moreover, the total number of electrically conductive structures provided in the other layers is further reduced, which is beneficial to reducing design difficulty, reducing the density of the electrically conductive structures provided in the other layers, and reducing parasitic capacitance caused by excessive density of electrically conductive structures.

For example, referring to FIGS. 2 and 3, the electrode ET where the active layer T1a of the first reset transistor T1 is located further includes the second electrode T1d of the first reset transistor T1, and the material of the second electrode T1d of the first reset transistor T1 is also the conducterized material of the second semiconductor material, and the second electrode T1d of the first reset transistor T1 also belongs to the conductorized portion of the electrode ET where the active layer T1a of the first reset transistor T1 is located. The pixel circuit further includes a first reset signal line LVini1 disposed in a different layer from the second electrode T1d of the first reset transistor T1, and the second electrode T1d of the first reset transistor T1 Is in contact with the first reset signal line LVini1 through a second via hole V2 exposing the first reset signal line LVini1 to directly electrically connect the first reset signal line LVini1. In this way, the second electrode T1d of the first reset transistor T1 (the material in which the second semiconductor material is made into a conductor) is electrically connected to the first reset signal line LVini1 through only the second via hole V2. There is no need to separately set a connection structure in other layers as in FIG. 4 (such as the second connection structure S2 in FIG. 4) to be electrically connected to the gate electrode T3g of the driving transistor T3 and the first electrode of the first reset transistor T1 through at least two via holes respectively, making full use of the electrode EL where the material of the active layer T1a of the first reset transistor T1 is located, simplifying the structure of the sub-pixel, reducing the connection wiring, and thus increasing the light transmittance. Moreover, the total number of electrically conductive structures provided in the other layers is further reduced, and the total number of connection vias is reduced, thereby simplifying the process of fabricating the vias, which is beneficial to reducing design difficulty and improving the yield of the display panel. At the same time, the density of the electrically conductive structures provided in the other layers is reduced, and parasitic capacitance caused by excessive density of the electrically conductive structures is reduced.

For example, referring to FIG. 3, the active layer T3a of the driving transistor T3 is arranged in different layers from the active layer T1a of the first reset transistor T1, and the gate electrode T3g of the driving transistor T3 is located between the active layer T3a of the driving transistor T3 and the electrode ET where the active layer T1a of the reset transistor T1 is located, that is, the gate electrode T3g of the driving transistor T3 is located on the side of the active layer T3a of the driving transistor T3 proximal to the electrode ET where the active layer T1a of the first reset transistor T1 is located, so that during the manufacturing process of the display substrate, the gate electrode T3g of the driving transistor T3 is in contact with the conductorized portion of the electrode ET where the active layer T1a of the first reset transistor T1 is located, without affecting the function of the driving transistor T3.

For example, referring to FIG. 3, the display substrate includes a base substrate BS, and the driving transistor T3 is disposed on a main surface of the base substrate BS. The active layer T3a of the driving transistor T3 is located on a side of the active layer T1a of the first reset transistor T1 proximal to the base substrate BS. That is, the active layer of the oxide transistor (Oxide TFT) is on upper side and the low-temperature polysilicon transistor (LTPS TFT) is on lower side. Here, the direction “lower side” is closer to the base substrate BS than the direction “upper side”. Therefore, in the manufacturing process of the display substrate, the active layer of the low-temperature polysilicon transistor (LTPS TFT) is first formed, and then the active layer of the oxide transistor (Oxide TFT) is formed. This is to avoid the impact on the performance of the oxide transistor (Oxide TFT) caused by the process of fabricating the active layer of the low-temperature polysilicon transistor (LTPS TFT) after forming the active layer of the oxide transistor (Oxide TFT) (e.g., IGZO).

For example, referring to FIGS. 2 and 4, the pixel circuit further includes a compensation transistor T2 configured to compensate a signal applied to the gate electrode T3g of the driving transistor T3 in response to the compensation scan signal and the data signal Vd. For example, the above-mentioned control transistor further includes a compensation transistor T2, and an electrode ET where an active layer T2a of the compensation transistor T2 is located is also directly electrically connected to the gate electrode T3g of the driving transistor T3 and the first electrode T2s of the compensation transistor T2. The electrode ET where the active layer T2a of the compensation transistor T2 is located is an integrated structure and includes the active layer T2a of the compensation transistor T2 and other parts, and the active layer T2a and other parts of the compensation transistor T2 constitute the electrode ET of the integrated structure. In this case, the material of the active layer T3a of the driving transistor T3 is the first semiconductor material, and the material of the active layer T2a of the compensation transistor T2 is the second semiconductor material. For example, the electrode ET where the active layer T2a of the compensation transistor T2 is located also includes a conductorized portion, which forms an integrated structure with the active layer T2a of the compensation transistor T2, and the conductorized portion is in contact with the first electrode T2s of the compensation transistor T2 and the gate electrode T3g of the driving transistor T3 respectively to achieve electrical connection with the two. For example, the material of the conductorized portion is a conductorized material of the second semiconductor material. In this way, the electrode ET where the active layer T2a of the compensation transistor T2 is located and having a conductorized portion is directly electrically connected to the gate electrode T3g of the driving transistor T3 and the first electrode T1s of the first reset transistor T1. On the one hand, the electrode ET where the active layer T1a of the first reset transistor T1 is located can be multi-used as a connection electrode to realize the electrical connection between the gate electrode T3g of the driving transistor T3 and the first electrode T2s of the compensation transistor T2, and there is no need to additionally provide a dedicated connection electrode in other layers (for example, in the electrically conductive layer on the side of the active layer T2a of the compensation transistor T2 distal to the base substrate BS) to be electrically connected to the gate electrode T3g of the driving transistor T3 and the first electrode T2s of the compensation transistor T2 through at least two via holes, thereby simplifying the structure of the pixel circuit. On the other hand, other signal lines such as data lines providing data signals Vd or connection electrodes for electrical connection between other elements of the pixel circuit can be provided in other layers without additionally providing connection electrodes to connect the gate electrode T3g of the driving transistor T3 and the first electrode T1s of the first reset transistor T1, thereby reducing the total number of electrically conductive structures provided in the other layers, which is beneficial to reducing the design difficulty, reducing the density of the electrically conductive structures provided in the other layers, reducing the parasitic capacitance generated due to excessive density of the electrically conductive structures, and improving the display quality.

For example, referring to FIG. 3, the electrode ET where the active layer T2a of the compensation transistor T2 is located includes the active layer T2a of the compensation transistor T2 and the first electrode T2s of the compensation transistor T2, and the materials of the active layer T2a of the compensation transistor T2 and the first electrode T2s of the compensation transistor T2 are all conductorized materials of the second semiconductor material, and belong to the conductorized portion of the electrode ET where the active layer T2a of the compensation transistor T2 is located; and the active layer T2a of the compensation transistor T2 and the first electrode T2s of the compensation transistor T2 are arranged in the same layer and form an integrated structure. The gate electrode T3g of the driving transistor T3 is arranged in different layers from the electrode where the active layer T2a of the compensation transistor T2 is located, and the first electrode T2s of the compensation transistor T2 is in contact with the gate electrode T3g of the driving transistor T3 through the third via V3 exposing the gate electrode T3g of the driving transistor T3 to directly electrically connect the gate electrode T3g of the driving transistor T3 and the first electrode T2s of the compensation transistor T2.

For example, in the embodiment shown in FIG. 3, the electrode ET where the active layer T2a of the compensation transistor T2 is located and the electrode ET where the active layer T1a of the first reset transistor T1 is located are arranged in the same layer and form an integrated structure, that is, the electrode ET where the active layer T2a of the compensation transistor T2 is located and the electrode ET where the active layer T1a of the first reset transistor T1 is located are the same electrode, the first electrode T1s of the first reset transistor T1 and the first electrode T2s of the compensation transistor T2 are integrated, and the first via hole V1 and the third via hole V3 are the same via hole. The electrode ET where the active layer T2a of the compensation transistor T2 is located further includes the first electrode T2s of the compensation transistor T2, the material of the active layer T2a of the compensation transistor T2 is the second semiconductor material, the material of the first electrode T2s of the compensation transistor T2 is the conductorized material of second semiconductor material; and the first electrode T1s of the first reset transistor T1, the first electrode T2s of the compensation transistor T2, and the active layer T2a of the compensation transistor T2 are connected in sequence, arranged in the same layer, and form an integrated structure.

For example, as shown in FIG. 3, the first electrode T1s of the first reset transistor T1 and the first electrode T2s of the compensation transistor T2 are adjacent and integrally formed to form a conductive connection portion CS, that is, the conductorized portion of the electrode ET where the active layer of the control transistor is located includes an electrically conductive connection portion CS, and the electrically conductive connection portion CS is electrically connected to the gate electrode T3g of the driving transistor T3 through the third via V3.

In the embodiment shown in FIG. 3, the same electrode ET including the active layer and the conductorized portion of the control transistor is used to realize the electrical connection between the gate electrode T3g of the driving transistor T3 and the first electrode T1s of the first reset transistor T1, the electrical connection between the gate electrode T3g of the driving transistor T3 and the first electrode T2s of the compensation transistor T2, and the electrical connection between the second electrode T1d of the first reset transistor T1 and the first reset signal line LVini1, thereby making full use of the active layer including the control transistor, greatly reducing the total number and density of electrically conductive structures provided in other layers (for example, the electrically conductive layer on the side of the active layer T1a of the first reset transistor T1 distal to or proximal to the substrate BS) for connecting the transistors, capacitors and other components of the sub-pixels, thereby greatly reducing the design difficulty, and also reducing the parasitic capacitance caused by the excessive density of electrically conductive structures in the other layers, and improving the display quality of the display substrate.

Of course, in other embodiments, the gate electrode T3g of the driving transistor T3 may be electrically connected to the first electrode T1s of the first reset transistor T1 without being electrically connected to the first electrode T2s of the compensation transistor T2. Alternatively, the gate electrode T3g of the driving transistor T3 is electrically connected to the first electrode T2s of the compensation transistor T2 but not electrically connected to the first electrode T1s of the first reset transistor T1. The above several ways can achieve the above technical effects of the display substrate provided by the present application to different extents and solve corresponding technical problems.

Referring to FIG. 2, the pixel circuit further includes a first light emission control transistor T6 configured to cause a driving current to be applied to the light emitting device EL under the control of the first light emission control signal EM1. Referring to FIG. 3, the material of the active layer T6a of the first emission control transistor T6 is the above-mentioned first semiconductor material (silicon semiconductor material), and the active layer Ta of the first emission control transistor T6 is arranged in different layers with the active layer of the control transistor (the active layer T1a of the first reset transistor T1 and/or the compensation transistor T2). The electrode where the active layer T2a of the compensation transistor T2 is located further includes a connection portion C1, the material of the connection portion C1 is a conductorized material of the second semiconductor material, and the connection portion C1 and the active layer T2a of the compensation transistor T2 are arranged in the same layer and constitute an integrated structure. The connection portion C1 contacts the active layer Toa of the first light emission control transistor T6 through the fourth via hole V4 exposing the active layer T6a of the first light emission control transistor T6 to be electrically connected to the active layer Toa of the first light emission control transistor T6, in this way, the connection portion C1 serves as the first electrode T6s of the first light emission control transistor T6 and the second electrode T2d of the compensation transistor T2.

For example, referring to FIG. 3, the active layer T6a of the first light emission control transistor T6 and the active layer T3a of the driving transistor T3 are arranged in the same layer, and/or, the gate electrode T3g of the driving transistor T3 and the gate electrode T6g of the first light emission control transistor T6 are arranged in the same layer, so that the same patterning process is performed on the same semiconductor layer (the material is the first semiconductor material) to form the active layer Toa of the first light emission control transistor T6 and the active layer T3a of the driving transistor T3, and the same patterning process is performed on the same electrically conductive layer to form the gate electrode T3g of the driving transistor T3 and the gate electrode T6g of the first light emission control transistor T6.

For example, referring to FIG. 3, the material of the active layer Toa of the first emission control transistor T6 is the above-mentioned first semiconductor material, and the active layer T6a of the first emission control transistor T6 is in a different layer from the active layer of the control transistor (the active layer T1a of the first reset transistor T1 and/or the compensation transistor T2). The electrode ET where the active layer of the control transistor is located is arranged in different layers from the second electrode T6d of the first light emission control transistor T6, and the electrode where the active layer of the control transistor is located is in contact with the active layer Toa of the first light emission control transistor T6 through the fourth via V4 exposing the active layer Toa of the first light emission control transistor T6, and the second electrode Tod of the first light emission control transistor T6 is in contact with the active layer Toa of the first light emission control transistor T6 through the fifth via V5 exposing the active layer Toa of the first light emission control transistor T6. For example, the second electrode Tod of the first light emission control transistor T6 is located in the electrically conductive layer SD1. In this way, the wiring of the electrically conductive layer SD1 is reduced, the situation of winding in the electrically conductive layer SD1 to avoid the structure of the same layer is avoided, the design difficulty of the electrically conductive layer SD1 is reduced, and the parasitic capacitance is avoided.

For example, referring to FIG. 3, the second electrode T6d of the first light emission control transistor T6 is located on the side of the electrode ET where the active layer of the control transistor is located distal to the base substrate BS, that is, the electrically conductive layer SD1 is located on the side of the active layer of the control transistor distal to the base substrate BS to avoid the second electrode Tod of the first light emission control transistor T6 being located between the electrode ET where the active layer of the control transistor is located and the gate electrode T6g of the first light emission control transistor T6, thereby avoiding interference with the arrangement of the electrode ET where the active layer of the control transistor is located and the gate electrode T6g of the first light emission control transistor T6, reducing the layout difficulty, and reducing the difficulty of the manufacturing process. While optimizing the above performance of the pixel circuit, reducing the difficulty of the manufacturing process, it is very important to ensure the yield of the product.

For example, the data line providing the above-mentioned data signal Vd is further located in the electrically conductive layer SD1, that is, provided in the same layer as the second electrode T6d of the first light emission control transistor T6. In the embodiment of the present disclosure, at least a connection electrode for electrically connecting the active layer of the first reset transistor T1 and the gate electrode of the driving transistor T3, a connection electrode for electrically connecting the active layer of the first reset transistor T1 and the gate electrode of the driving transistor T3, and a connection electrode for electrically connecting the active layer of the first reset transistor and the first reset signal line are not present in the electrically conductive layer SD1, thereby greatly reducing the total number of wires or electrically conductive structures in the electrically conductive layer SD1, reducing the density of wires or electrically conductive structures provided in the electrically conductive layer SD1, reducing parasitic capacitance generated due to excessive density of electrically conductive structures, and improving display quality.

For example, in the embodiment shown in FIG. 3, the first reset signal line LVini1 and the second electrode T6d of the first light emission control transistor T6 are arranged in different layers to prevent the first reset signal line LVini1 from being located in the electrically conductive layer SD1 and causing the first reset signal line LVini1 to have a winding design while avoiding other electrically conductive structures, that is, bypassing other structures to avoid intersecting with other electrically conductive structures. For example, FIG. 5 is a schematic planar structural diagram of a current pixel circuit. Referring to FIG. 5, the circuit diagram of the pixel circuit may be, for example, the equivalent circuit shown in FIG. 2, and the rectangular dotted line frame in FIG. 5 is a schematic diagram of the planar structure of the pixel circuit of a sub-pixel unit. Referring to FIG. 5, the first scan line LGa1 provides the first scan signal Ga1 (the data scan signal) in FIG. 2, the second scan line LGa2 provides the second scan signal (the compensation scan signal) Ga2 in FIG. 2, and the light emission control scan line LEM provides the first light emission control signal EM1 and the second light emission control signal EM2 in FIG. 2, the first reset scan line LRst1 provides the first reset scan signal Rst1 in FIG. 2, and the second reset scan line LRst2 provides the second reset scan signal Rst2 in FIG. 2. The first reset signal line LV1 is arranged in the same layer as the first connection electrode S1 that implements the first node N1 in FIG. 2 (that is, the first connection electrode S1 in FIG. 4). In order to avoid the first connection electrode S1, the first reset signal line LV1 adopts a winding design that is, meandering upward and then extending to the right, including the winding portion R. On the one hand, the above solution shown in FIG. 5 will increase the parasitic capacitance between the electrically conductive layer SD1 and other electrically conductive layers. On the other hand, due to wiring difficulties, the first reset signal line LV1 has to pass directly above the channel region of the first reset transistor T1 (near the position indicated by T1 in FIG. 5), which will affect the switching characteristics of the first reset transistor T1. However, in the display substrate provided by the embodiment of the present application, since the electrode ET where the active layer of the control transistor is located (the conductorized portion of the electrode ET where the active layer of the control transistor is located) is directly electrically connected to the gate electrode T3g of the driving transistor T3 and the first electrode of the control transistor, there is no need to additionally provide a conductorized portion in the electrically conductive layer SD1 specifically for electrically connecting the gate electrode T3g of the driving transistor T3 and the electrode ET where the active layer of the control transistor is located, thereby reducing the total number and density of electrically conductive structures in the electrically conductive layer SD1. It solves the technical problem of excessive parasitic capacitance caused by excessive winding due to excessive density of electrically conductive structures in the electrically conductive layer SD1 and affecting the switching characteristics of the first reset transistor T1. Furthermore, since the first reset signal line LVini1 and the second electrode T6d of the first light emission control transistor T6 are arranged in different layers, the above technical problem can be further solved.

For example, referring to FIG. 3, the first reset signal line LVini1 and the gate electrode T3g of the driving transistor T3 are both located between the active layer T3a of the driving transistor T3 and the electrodes ET where the active layer of the control transistor (the active layer T1a of the first reset transistor T1 and/or the active layer T2a of the compensation transistor T2) is located. For example, referring to FIG. 3, for example, the first reset signal line LVini1 and the gate electrode T3g of the driving transistor T3 are arranged in different layers to avoid excessive density of the electrically conductive structure in the electrically conductive layer where they are located, especially for high PPI displays substrate, the space of each sub-pixel is more limited, so that the structure of the pixel circuit can meet the requirements of display substrates with higher PPI. For example, the gate electrode T3g of the driving transistor T3 is located in the first electrically conductive layer Gate1, the first reset signal line L Vini1 is located in the second electrically conductive layer Gate2, and the second electrically conductive layer Gate2 is located on the side of the first electrically conductive layer Gate1 distal to the base substrate BS. In this way, in a direction perpendicular to the main surface of the base substrate BS, the second electrically conductive layer Gate2 is closer to the electrode ET where the active layer T1a of the first reset transistor T1 is located, so that the active layer T1a of the first reset transistor T1 contacts the first reset signal line LVini1 located in the second electrically conductive layer Gate2 through the second via V2 for electrical connection.

Alternatively, in other embodiments, the first reset signal line LVini1 and the gate electrode T3g of the driving transistor T3 may also be provided in the same layer.

For example, in the embodiment shown in FIG. 3, the control transistor is a double-gate transistor. For example, the first reset transistor T1 and the compensation transistor T2 are both double-gate transistors, the first reset transistor T1 includes a first gate electrode T1g1 and a second gate electrode T1g2, and the compensation transistor T2 includes a first gate electrode T2g1 and a second gate electrode T2g2. Of course, at least one of the first reset transistor T1 and the compensation transistor T2 is a double-gate transistor, and the first gate electrode of the control transistor (the first gate electrode T1g1 of the first reset transistor T1 and/or the first gate electrode T2g1 of the compensation transistor T2) is located on the side of the active layer of the control transistor distal to the active layer T3a of the driving transistor T3, for example, on the third electrically conductive layer Gate3. The second gate electrode of the control transistor (the second gate electrode T1g2 of the first reset transistor T1 and/or the second gate electrode T2g2 of the compensation transistor T2) is located between the active layer of the control transistor (the active layer T1a of the first reset transistor T1 and/or the active layer T2a of the compensation transistor T2) and the active layer T3a of the driving transistor T3, and the second gate electrode of the control transistor (the second gate electrode T1g2 of the first reset transistor T1 and/or the second gate electrode T2g2 of the compensation transistor T2) is arranged in the same layer as the first reset signal line LVini1, for example, both are located in the second electrically conductive layer Gate2.

Alternatively, in other embodiments, the second gate electrode of the control transistor and the first reset signal line LVini1 may be provided in different layers.

For example, referring to FIG. 3, the second gate electrode T1g2 of the first reset transistor T1 and/or the second gate electrode T2g2 of the compensation transistor T2 is arranged along a lateral direction with the gate electrode T3g of the driving transistor T3, for example, it is parallel to the main surface of the base substrate BS along the lateral direction, that is, the second gate electrode of the control transistor and the gate electrode T3g of the driving transistor T3 are arranged along the lateral direction. In the case where the control transistor is a double-gate transistor, the line width of the second gate electrode of the control transistor in the lateral direction is larger than the line width of the first gate electrode of the control transistor in the lateral direction. For example, the line width of the second gate electrode T1g2 of the first reset transistor T1 in the lateral direction is greater than the line width of the first gate electrode T1g1 of the first reset transistor T1 in the lateral direction, and the line width of the second gate electrode T2g2 of the compensation transistor T2 in the lateral direction is greater than the line width of the first gate electrode T2g1 of the compensation transistor T2 in the lateral direction.

For example, referring to FIG. 3, the first reset signal line LVini1 and the gate electrode of the control transistor do not overlap in a direction perpendicular to the main surface of the base substrate BS to avoid the parasitic capacitance caused by the two overlapping in a direction perpendicular to the main surface of the base substrate BS.

For example, referring to FIG. 3, the display substrate further includes a first flexible layer PI1, a first barrier layer Barrier1, a second flexible layer PI2, a second barrier layer Barrier2-1, a bottom shield electrode BSM, a third barrier layer Barrier2-2, a first buffer layer Buffer1, a first gate insulating layer GI1, a second gate insulating layer GI2, a first interlayer insulating layer ILD1, a second buffer layer Buffer2, a third gate insulating layer GI3 and a second interlayer insulating layer ILD2, all of which are disposed on the base substrate BS. Each insulating layer realizes direct insulation of each electrically conductive layer, and each buffer layer can isolate impurities for the subsequent film layer formed on the corresponding buffer layer. The material of the first flexible layer PI1 and the second flexible layer PI2 is, for example, polyimide (PI) so that the display substrate is a flexible substrate. The substrate including polyimide (PI) contains movable fixed charges. When the gate voltage of the driving transistor T3 changes, the movable charges move up and down as the electric field formed by the gate voltage of the driving transistor T3 changes. Movement forms a built-in electric field that changes with the gate voltage of the driving transistor T3, thereby affecting the characteristics of the driving transistor T3 and the image quality of the display substrate. When a fixed voltage is applied to the bottom shield electrode BSM, the influence of the fixed charge in the polyimide (PI) on the characteristics of the driving transistor T3 can be shielded, thereby improving the display quality. For example, the bottom shield electrode BSM is connected to the first voltage signal VDD.

FIG. 6 is a partial cross-sectional schematic diagram of a pixel circuit of another display substrate provided by an embodiment of the present disclosure. The technical solution of FIG. 6 has the following differences from the technical solution of FIG. 3 mentioned above.

Referring to FIG. 6, the electrode ET where the active layer T2a of the compensation transistor T2 is located further includes the second electrode T2d of the compensation transistor T2, and the material of the second electrode T2d of the compensation transistor T2 is the conductorized material of the above-mentioned second semiconductor material, the second electrode T2d of the compensation transistor T2 and the active layer T2a of the compensation transistor T2 are arranged in the same layer and form an integrated structure; The pixel circuit includes a first connection structure CS1, and the first connection structure CS1, the second electrode T2d of the compensation transistor T2 and the electrode ET where the active layer of the control transistor is located are all arranged in different layers from each other. For example, the first connection structure CS1 and the second electrode Tod of the first light emission control transistor T6 are provided in the same layer, for example, both are located in the electrically conductive layer SD1. The first connection structure CS1 is electrically connected to the second electrode T2d of the compensation transistor T2 through the sixth via hole V6, and is electrically connected to the active layer T6a of the first light emission control transistor T6 through the seventh via hole V7. In the embodiment shown in FIG. 6, directly electrically connecting the gate electrode T3g of the driving transistor T3 and the first electrode of the control transistor through the electrode ET where the active layer of the control transistor is located can also greatly simplify the structure of the pixel circuit, and there is no need to provide additional connection electrodes in other layers to connect the gate electrode T3g of the driving transistor T3 and the first electrode of the control transistor, thereby reducing the total number of electrically conductive structures provided in the other layers. Moreover, in the embodiment shown in FIG. 6, the first connection structure CS1 is in contact with the second electrode T2d of the compensation transistor T2 and the active layer Toa of the first light emission control transistor T6 through the sixth via hole V6 and the seventh via hole V7 respectively to electrically connect the two. The material of the first connection structure CS1 can be a common electrically conductive material, for example, a metal electrically conductive material, such as aluminum, copper, chromium, etc. and their alloys. It can also avoid the problem of large contact resistance caused by direct contact with P—Si and thus electrical connection. This improves the display uniformity of the pixel array of the display substrate and improves the display effect.

Referring to FIG. 6, for example, the sixth via hole V6 penetrates the second electrode T2d of the compensation transistor T2 in a direction perpendicular to the main surface of the base substrate BS, and the first connection structure CS1 includes an in-hole portion PIV located in the sixth via hole V6, the side surface of the part PIV in the hole is in contact with the second electrode T2d of the compensation transistor T2 to be electrically connected to the second electrode T2d of the compensation transistor T2, and the surface where the side surface of the part PIV in the hole is located intersects with the surface where the main surface of the base substrate BS is located, that is, the surface of the part PIV in the hole is in contact with the hole wall of the hole penetrating the second electrode T2d of the compensation transistor T2. FIG. 6 uses a side connection manner to electrically connect the first connection structure CS1 to the second electrode T2d of the compensation transistor T2.

Other features and corresponding technical effects of the embodiment shown in FIG. 6 are the same as those in FIG. 3, and reference can be made to the previous description.

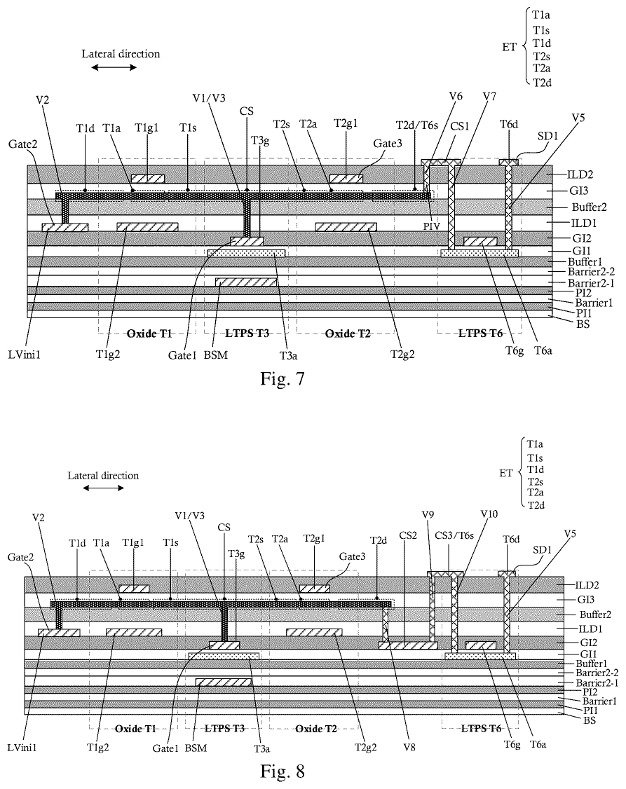

FIG. 7 is a partial cross-sectional schematic diagram of a pixel circuit of yet another display substrate provided by at least one embodiment of the present disclosure. The technical solution of FIG. 7 has the following differences from the technical solution of FIG. 6 mentioned above.

Referring to FIG. 7, the sixth via hole V6 exposes the upper surface of the second electrode T2d of the compensation transistor T2, and the upper surface of the second electrode T2d of the compensation transistor T2 is distal to the main surface of the substrate BS, and the first connection structure CS1 includes an in-hole portion PIV in the sixth via hole V6, the bottom surface (the surface facing towards the substrate BS) of the in-hole portion PIV is in contact with the upper surface of the second electrode T2d of the compensation transistor T2 to be electrically connected to the second electrode T2d of the compensation transistor T2. FIG. 7 uses a bottom connection manner to electrically connect the first connection structure CS1 to the second electrode T2d of the compensation transistor T2.

On the basis of the technical effects achieved by the embodiment of FIG. 3, the display substrate shown in FIG. 7 can also avoid the larger contact resistance caused by direct contact between the conductorized portion of the electrode ET made from conductive IGZO and P—Si and thus an electrical connection, thereby achieving better display uniformity of the pixel array of the display substrate and improving the display effect.

Other features and corresponding technical effects of the embodiment shown in FIG. 7 are the same as those in FIG. 6 or FIG. 3, and reference can be made to the previous description.

FIG. 8 is a partial cross-sectional schematic diagram of a pixel circuit of yet another display substrate provided by at least one embodiment of the present disclosure. The technical solution of FIG. 8 has the following differences from the technical solution of FIG. 6 mentioned above.

Referring to FIG. 8, the material of the active layer T6a of the first light emission control transistor T6 is a first semiconductor material, and the active layer Toa of the first light emission control transistor T6 is arranged in different layers from the active layer of the control transistor. The electrode ET where the active layer T2a of the compensation transistor T2 is located further includes the second electrode T2d of the compensation transistor T2, and the material of the second electrode T2d of the compensation transistor T2 is the conductorized material of the second semiconductor material, that is, the conductorized portion of the electrode ET includes the second electrode T2d of the compensation transistor T2. The second electrode T2d of the compensation transistor T2 is arranged in the same layer as the active layer T2a of the compensation transistor T2 and forms an integrated structure. The pixel circuit includes a second connection structure CS2 and a third connection structure CS3, and the second electrode T2d of the compensation transistor T2, the second connection structure CS2, the third connection structure CS3 and the active layer T6a of the first light emission control transistor T6 are all arranged in different layers from each other. The second electrode T2d of the compensation transistor T2 is electrically connected to the second connection structure CS2 through the eighth via hole V8, the third connection structure CS3 is electrically connected to the second connection structure CS2 through the ninth via hole V9, and the third connection structure CS3 is electrically connected to the active layer Toa of the first light emission control transistor T6 through the tenth via hole V10, so that the third connection structure CS3 serves as the first electrode T6s of the first light emission control transistor T6. On the basis of the technical effects achieved by the embodiment of FIG. 3, the display substrate shown in FIG. 8 can also avoid the larger contact resistance caused by direct contact between the conductorized portion of the electrode ET made from conductive IGZO and P—Si and thus electrical connection, thereby achieving better display uniformity of the pixel array of the display substrate and improving the display effect.

For example, referring to FIG. 8, the second connection structure CS2 is arranged in the same layer as the gate electrode Tog of the first light emission control transistor T6, and is located in the first electrically conductive layer Gate1; for example, the third connection structure CS3 is arranged in the same layer as the second electrode Tod of the first light emission control transistor T6, that is, in the electrically conductive layer SD1.

Other features and corresponding technical effects of the embodiment shown in FIG. 8 are the same as those in FIG. 6 or FIG. 3, and reference can be made to the previous description.

For example, in some embodiments of the present disclosure, the control transistor may be a single-gate transistor, and the gate electrode of the control transistor is located on a side of the active layer of the control transistor distal to the active layer of the driving transistor. Here the control transistor may still comprise at least one of the first reset transistor T1 and the compensation transistor T2.

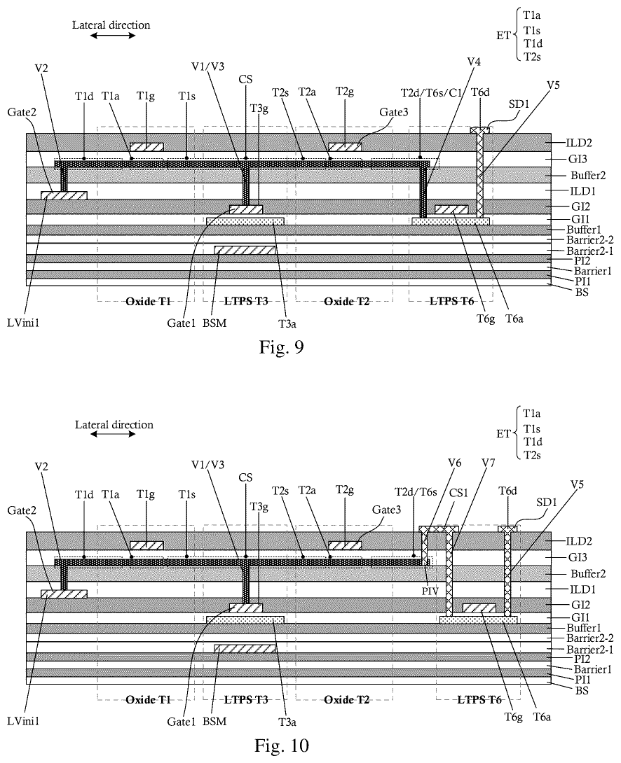

Exemplarily, FIG. 9 is a partial cross-sectional schematic diagram of a pixel circuit of another display substrate provided by at least one embodiment of the present disclosure. The technical solution of FIG. 9 has the following differences from the technical solution of FIG. 3 mentioned above. Referring to FIG. 9, for example, at least one of the first reset transistor T1 and the compensation transistor T2 is a single-gate transistor. FIG. 9 shows the case where both the first reset transistor T1 and the compensation transistor T2 are single-gate transistors, the first reset transistor T1 has a gate electrode T1g, and the compensation transistor T2 has a gate electrode T2g. For example, the gate electrode T1g of the first reset transistor T1 is located on a side of the active layer T1a of the first reset transistor T1 distal to the base substrate BS, and the gate electrode T2g of the compensation transistor T2 is located on a side of the active layer T2a of the compensation transistor T2 distal to the base substrate BS. For example, the gate electrode T1g of the first reset transistor T1 and the gate electrode T2g of the compensation transistor T2 are arranged in different layers from the first reset signal line Lvini1 and the gate electrode T3g of the driving transistor T3 to avoid excessive density of the electrically conductive structure in the same layer. Excessive parasitic capacitance or increased manufacturing difficulty, especially when the space for each sub-pixel in a high-resolution (high PPI) display substrate is more limited, this problem has a greater impact on the display effect. For example, referring to FIG. 9, the gate electrodes T1g and T2g are located in the third electrically conductive layer Gate3; the first reset signal line Lvini1 is located in the second electrically conductive layer Gate2; the gate electrode T3g of the driving transistor T3 is located in the first electrically conductive layer Gate1. This situation is a preferred embodiment in consideration of ease of production and prevention of excessive density of electrically conductive structures in the same layer. However, the electrically conductive layer where the gate electrode T1g, the gate electrode T2g, and the gate electrode T3g are located is not limited to this embodiment.

For example, a method for manufacturing a pixel circuit provided by at least one embodiment of the present application includes: forming a first type of via hole, which exposes at least an active layer made from a first semiconductor material (for example, P—Si), and forming a first electrically conductive structure to be electrically connected to a surface of the active layer exposed by the first type of via hole through the first type of via hole. After forming the first type of via hole, in order to improve the characteristics of the LTPS TFT device, a high-temperature annealing process is performed on the display substrate. For example, the manufacturing method of the pixel circuit includes: subjecting the surface of the active layer made of the first semiconductor material exposed by the first type of via hole to a contact resistance reduction treatment to reduce the contact resistance of the exposed surface, for example, enabling the surface to be in ohmic contact with the electrically conductive structure which is in contact with the surface through the first type of via hole. For example, the surface of the active layer of the first semiconductor material exposed by the first type of the via hole may be etched to remove the oxide layer of the exposed surface, thereby reducing the contact resistance of the exposed surface. For example, the first type of via hole includes a fifth via hole V5 exposing the active layer T6a of the first light emission control transistor T6.

For example, the manufacturing method of the pixel circuit provided in the embodiment of the present application further includes: forming a second electrically conductive structure, wherein the second electrically conductive structure is an electrode where the active layer of the above-mentioned control transistor is located, and the second electrically conductive structure includes the active layer of the control transistor and a conductorized portion that forms an integrated structure with the active layer of the control transistor, the active layer of the control transistor is made from a second semiconductor material (for example, IGZO), and the conductorized portion is a conductorized portion of the second semiconductor material. The method further comprises: forming a second type of via hole, wherein the conductivized portion of the second electrically conductive structure is in contact with a structure exposed by the second type of the via hole for electrical connection. For example, the conductivized portion of the second electrically conductive structure is directly electrically connected to the gate electrode of the driving transistor and the first electrode of the control transistor through the second type of via hole. For example, the above-mentioned contact resistance reduction process can be performed after forming the second type of the via hole and before forming the second electrically conductive structure, so that the contact resistance reduction process does not affect the performance of the control transistor and maintains the stability of the characteristics of the control transistor. Therefore, the control transistor can achieve ideal performance using a single gate, thereby simplifying the structure.

Referring to FIG. 9, compared with the structure shown in FIG. 3, for the first reset transistor T1, the first gate electrode T1g1 with a smaller length in the lateral direction remains, and the second gate electrode T1g2 with a larger length in the lateral direction is removed. Similarly, for the compensation transistor T2, the first gate electrode T2g1 with a smaller length in the lateral direction remains, and the second gate electrode T2g2 with a larger length in the lateral direction is removed. In this way, the length of the gate electrode of the control transistor (the first reset transistor T1 and/or the compensation transistor T2) in the lateral direction is reduced. For example, in the embodiment in which the control transistor adopts a single-gate structure shown in FIG. 9, the length of the first gate electrode T1g1 of the first reset transistor T1 and/or the first gate electrode T2g1 of the compensation transistor T2 along the lateral direction is less than the length of the gate electrodes of other transistors of the pixel circuit along the lateral direction, for example, less than the length of the gate electrode of the driving transistor T3 along the lateral direction, or less than the length of the gate electrode of the first light emission control transistor T6 along the lateral direction, etc. Because the material of the gate electrode is usually an opaque electrically conductive material such as a metal material, the above-mentioned length of the gate electrode of the single-gate control transistor is reduced, which can improve the aperture ratio of the display substrate. In addition, for the corresponding control transistor, taking the first reset transistor T1 as an example, the length of the channel region of the first reset transistor T1 in the direction of the first electrode T1s of the first reset transistor T1 to the second electrode T1d of the first reset transistor T1 is L, that is, the length in the lateral direction in FIG. 9 is L, and the width of the channel region in the direction perpendicular to the lateral direction is W. Therefore, when W remains unchanged, L decreases, which can increase the width-to-length ratio W/L of the first reset transistor T1, that is, increase the width-to-length ratio of the first reset transistor T1, which is beneficial to reducing the heat generation of the first reset transistor T1 and increasing the life of the first reset transistor T1. The same is true for the compensation transistor T2 having a single gate with a smaller length.

Other features and corresponding technical effects of the embodiment shown in FIG. 9 are the same as those in FIG. 3, and reference can be made to the previous description.

FIG. 10 is a partial cross-sectional schematic diagram of a pixel circuit of another display substrate provided by at least one embodiment of the present disclosure. The technical solution of FIG. 10 has the following differences from the technical solution of FIG. 6 mentioned above. Referring to FIG. 10, for example, at least one of the first reset transistor T1 and the compensation transistor T2 is a single-gate transistor. FIG. 10 shows the case where both the first reset transistor T1 and the compensation transistor T2 are single-gate transistors, the first reset transistor T1 has a gate electrode T1g, and the compensation transistor T2 has a gate electrode T2g.

Other features and corresponding technical effects of the first reset transistor T1 having the gate electrode T1g and the compensation transistor T2 having the gate electrode T2g shown in FIG. 10 are the same as those in FIG. 9. Please refer to the description of FIG. 9 and will not be repeated here.

Other unmentioned features and corresponding technical effects of the embodiment shown in FIG. 10 are the same as those in FIG. 6, and reference can be made to the previous description.

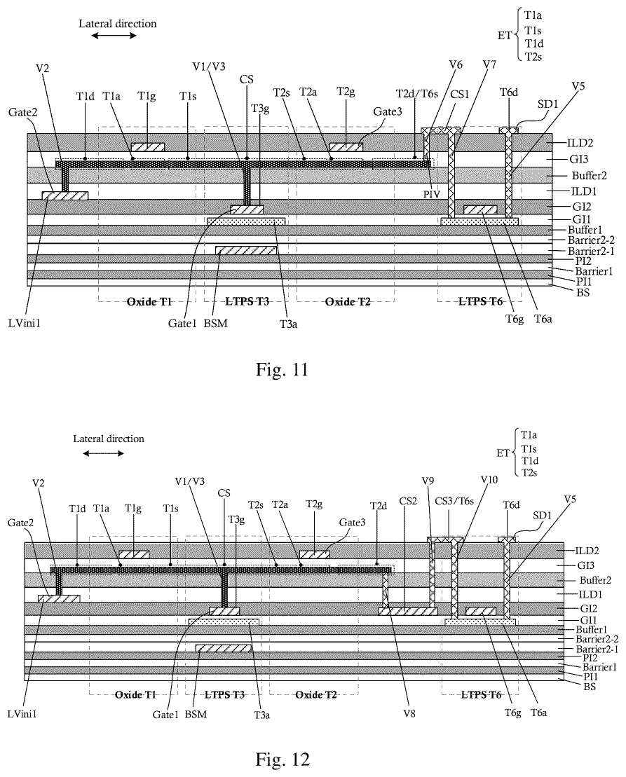

FIG. 11 is a partial cross-sectional schematic diagram of a pixel circuit of another display substrate provided by at least one embodiment of the present disclosure. The technical solution of FIG. 11 has the following differences from the technical solution of FIG. 7 mentioned above. Referring to FIG. 11, for example, at least one of the first reset transistor T1 and the compensation transistor T2 is a single-gate transistor. FIG. 11 shows the case where both the first reset transistor T1 and the compensation transistor T2 are single-gate transistors, the first reset transistor T1 has a gate electrode T1g, and the compensation transistor T2 has a gate electrode T2g.

Other features and corresponding technical effects of the first reset transistor T1 having the gate electrode T1g and the compensation transistor T2 having the gate electrode T2g shown in FIG. 11 are the same as those in FIG. 9. Please refer to the description of FIG. 9 and will not be repeated here.

Other unmentioned features and corresponding technical effects of the embodiment shown in FIG. 11 are the same as those in FIG. 7, and reference can be made to the previous description.

FIG. 12 is a partial cross-sectional schematic diagram of a pixel circuit of another display substrate provided by at least one embodiment of the present disclosure. The technical solution of FIG. 12 has the following differences from the technical solution of FIG. 8 mentioned above. Referring to FIG. 12, for example, at least one of the first reset transistor T1 and the compensation transistor T2 is a single-gate transistor. FIG. 12 shows the case where both the first reset transistor T1 and the compensation transistor T2 are single-gate transistors, the first reset transistor T1 has a gate electrode T1g, and the compensation transistor T2 has a gate electrode T2g.

Other features and corresponding technical effects of the first reset transistor T1 having the gate electrode T1g and the compensation transistor T2 having the gate electrode T2g shown in FIG. 12 are the same as those in FIG. 9. Please refer to the description of FIG. 9 and will not be repeated here.

Other unmentioned features and corresponding technical effects of the embodiment shown in FIG. 12 are the same as in FIG. 8, and reference can be made to the previous description.

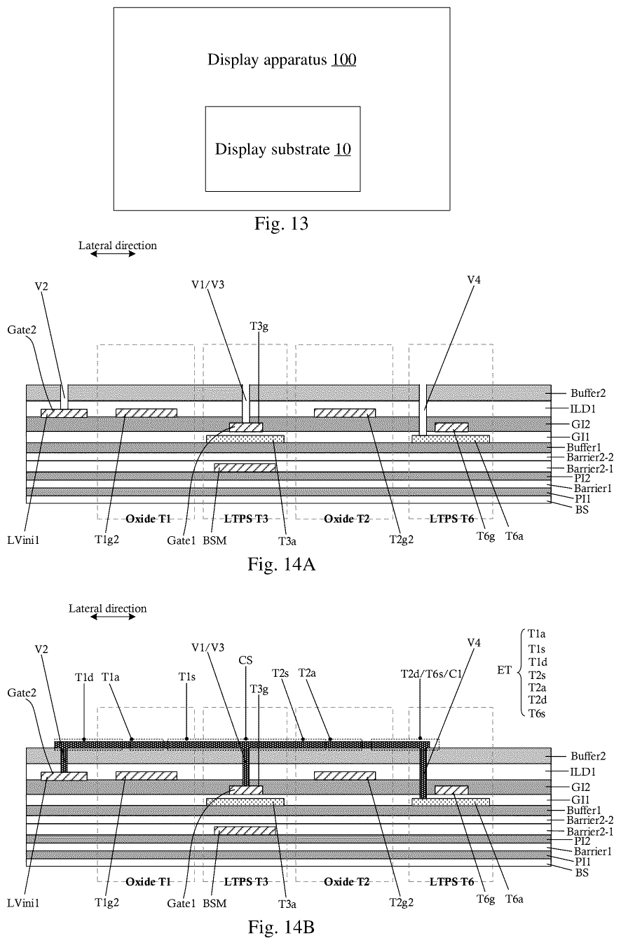

FIG. 13 is a schematic diagram of a display apparatus provided by an embodiment of the present disclosure. Referring to FIG. 13, at least one embodiment of the present disclosure further provides a display apparatus 100, which includes any display substrate 10 provided by the embodiment of the present disclosure. The display apparatus may be, for example, a display panel, or any product or component with a display function such as a display, an OLED panel, an OLED TV, electronic paper, a mobile phone, a tablet computer, a notebook computer, a digital photo frame, a navigator, etc. Of course, the display apparatus provided by the embodiment of the present disclosure is not limited to the types listed above.

Correspondingly, the display panel and the display apparatus provided by the embodiments of the present disclosure both have the technical effects of the pixel circuit and the display substrate provided by the implementation of the present disclosure.

At least one embodiment of the present disclosure further provides a method for manufacturing a display substrate, which includes: forming a sub-pixel, including forming a pixel circuit, wherein the forming the pixel circuit includes: forming a light-emitting device and a driving transistor, and the driving transistor is configured to control the magnitude of the driving current flowing through the light-emitting device according to data signal. The forming of the pixel circuit further includes: forming a control transistor, wherein a first electrode of the control transistor is electrically connected to a gate electrode of the driving transistor; the material of an active layer of the driving transistor is a first semiconductor material and the material of the active layer of the control transistor is a second semiconductor material, the first semiconductor material being different from the second semiconductor material; the electrode where the active layer of the control transistor is located is directly electrically connected to the gate electrode of the driving transistor and the first electrode of the control transistor.

For example, the manufacturing method of the display substrate includes: using the second semiconductor material to form a second semiconductor layer through a patterning process; conductorizing a portion of the second semiconductor layer to form a second electrically conductive structure, wherein the second electrically conductive structure serves as an electrode where the active layer of the control transistor is located, and includes a conductorized portion and a non-conductorized portion, and the conductorized portion and the non-conductorized portion constitute an integrated structure. The non-conductorized portion constitutes the active layer of the control transistor, the conductorized portion directly and electrically connects the gate electrode of the driving transistor and the first electrode of the control transistor, and the material of the conductorized portion is the conductorized material of the second semiconductor material. The method further comprises: forming a second type of via hole, the conductorized portion of the second electrically conductive structure is directly electrically connected to the gate electrode of the driving transistor and the first electrode of the control transistor through the second type of via hole.

“Directly electrically connected” here means that at least part of the conductorized portion is in direct contact with the gate electrode of the driving transistor and the first electrode of the control transistor to be electrically connected thereto, rather than the conductorized portion is indirectly connected to the gate electrode of the driving transistor and the first electrode of the control transistor through other non-integrated electrically conductive structures or even electrically conductive structures arranged in different layers.

For example, the conductorized portion of the electrode where the active layer of the control transistor is located includes the first electrode of the control transistor, and the first electrode of the control transistor and the active layer of the control transistor are arranged in the same layer and form an integrated structure.

In this way, in the manufacturing method of the display substrate provided by the embodiment of the present disclosure, the second semiconductor layer can be formed through a single patterning process, and the total number of electrodes and via holes used for switching are reduced, simplifying the manufacturing process and design difficulty of the display substrate, greatly reducing the density of electrically conductive structures in the same layer and reducing the wiring difficulty of electrically conductive structures or wires in the same layer, which plays an important role in improving the yield of the display substrate.

In a common manufacturing method of the display substrate, for example, in the manufacturing process of the display substrate shown in FIG. 4, typically, after forming the first type of via hole, taking the first type of via hole including the via hole V01 that exposes the surface of the active layer T60a (made from the first semiconductor material) of the first light emission control transistor T6 as an example, an etching process is performed on the surface of the active layer T60a exposed by the via hole V01 to remove the oxide film on its surface, thereby reducing the contact resistance. Then, a process of forming the via hole V02 on the surface of the active layer T10a/T20a made from the second semiconductor material is performed, and then the first connection structure S1, the second connection structure S2 and the third connection structure S3 are formed to utilize the first connection structure S1, the second connection structure S2 and the third connection structure S3 electrically connect the first reset transistor T1, the compensation transistor T2 and the first light emission control transistor T6 through the via hole V01 and the via hole V02. In this manufacturing method, from the etching process performed on the surface of the active layer T60a exposed by the via hole V01 to the formation of the first connection structure S1, the second connection structure S2 and the third connection structure S3 (for example, usually formed by deposition or sputtering), a certain period of time needs to be left in between. During this period of time, on the one hand, an oxide layer is possibly formed again on the surface of the active layer T60a exposed by the via hole V01, thereby affecting the ohmic contact between the active layer T60a and the third connection structure S3. On the other hand, the presence of foreign matter such as impurity particles in part of the via hole V01 my affect the electrical connection between the active layer T60a and the third connection structure S3, thereby affecting the yield of the display substrate.

For example, the manufacturing method of a pixel circuit provided by at least one embodiment of the present application includes: forming a first type of via hole, which exposes at least an active layer made from a first semiconductor material (for example, P—Si), and forming a first electrically conductive structure to be electrically connected, through the first type of via hole, to the surface of the active layer made from the first semiconductor material exposed by the first type of via hole. After forming the first type of via hole, in order to improve the characteristics of the LTPS TFT device, a high-temperature annealing process is performed on the display substrate. For example, the manufacturing method of the pixel circuit includes: performing a contact resistance reduction treatment on the surface of the active layer made from the first semiconductor material and exposed by the first type of via hole to reduce the contact resistance of the exposed surface, for example, to enable the surface to be in ohmic contact with the electrically conductive structure in contact with it through the first type of via hole. For example, the surface of the active layer made from the first semiconductor material and exposed by the first type of the via hole may be etched to remove the oxide layer of the exposed surface, thereby reducing the contact resistance of the exposed surface. For example, the first type of via hole includes a fifth via hole V5 exposing the active layer T6a of the first light emission control transistor T6.

For example, the manufacturing method of the pixel circuit provided in the embodiment of the present application further includes: forming a second type of via hole, and forming a second electrically conductive structure in the second type of via hole; the electrode where the second electrically conductive structure is located includes the active layer of the above-mentioned control transistor, the active layer of the control transistor is made from a second semiconductor material (for example, IGZO), and the electrode where the second electrically conductive structure is located further includes a conductorized portion which constitutes an integrated structure with the active layer of the control transistor. The conductorized portion is a conductorized material of the second semiconductor material. For example, a portion of the second electrically conductive structures located in the second type of the via hole are in contact, through the second type of the via hole, with structures exposed by the second type of the via hole for electrical connection. For example, the above-mentioned contact resistance reduction process can be performed after forming the second type of the via hole and before forming the second electrically conductive structure, so that the contact resistance reduction process does not affect the performance of the control transistor. Therefore, the control transistor can achieve the desired performance using a single gate, thereby simplifying the structure.

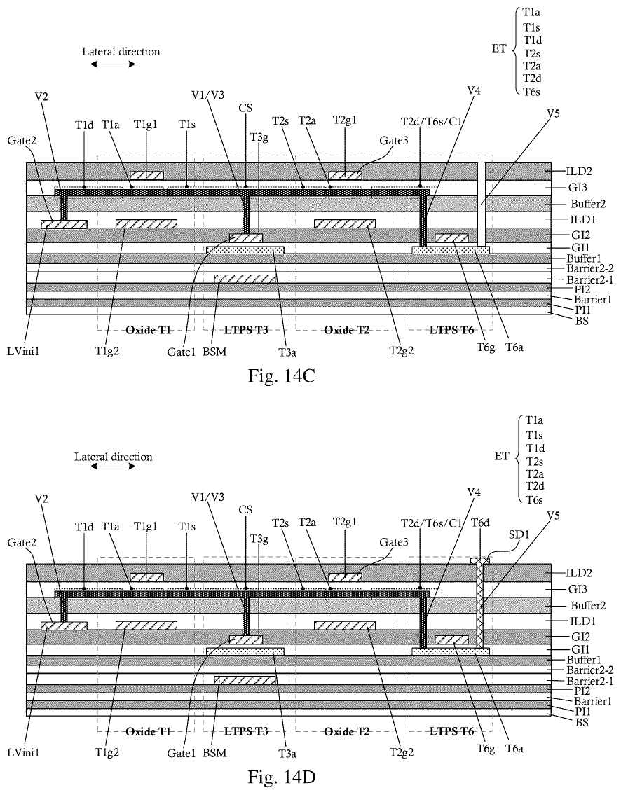

Exemplarily, FIGS. 14A to 14D are schematic diagrams of a method for manufacturing a display substrate provided by an embodiment of the present disclosure. For example, FIGS. 14A to 14D show the method for manufacturing the display substrate shown in FIG. 3.

Referring to FIG. 14A, a base substrate BS is provided, and a first flexible layer PI1, a first barrier layer Barrier1, a second flexible layer PI2, a second barrier layer Barrier2-1, a bottom shield electrode BSM, and a third barrier layer Barrier2, a first buffer layer Buffer1, active layers made from first semiconductor materials including but not limited to the active layer T3a of the driving transistor T3 and the active layer Toa of the first light emission control transistor T6, a first gate insulating layer GI1, a first metal layer Gate1, a second gate insulating layer GI2, a second metal layer Gate2, a first interlayer insulating layer ILD1 and a second buffer layer Buffer2 are formed on the base substrate BS. Then, the above-mentioned second type of via holes are formed through a patterning process. Here, the second type of via holes includes the first via hole V1, the second via hole V2 (in this embodiment, the second via hole V2 is also the third via hole V3), and the fourth via V4. For example, these three second type of via holes are formed in a single pixel circuit. Of course, the total number of the second type of the via holes is not limited to this case.

Next, referring to FIG. 14B, a second semiconductor layer (not shown) is formed using the above-mentioned second semiconductor material, for example, a deposition method is used to form the second semiconductor layer, and a single patterning process is performed on the second semiconductor layer to form a connection electrode pattern. Then, a part of the connection electrode pattern is subjected to a conductorizing treatment to form a second electrically conductive structure, a part of the second electrically conductive structure is located in the first via hole V1, the second via hole V2 and the fourth via hole V4, the second electrically conductive structure is the electrode ET where the active layer of the above-mentioned control transistor is located, and the second electrically conductive structure includes the active layer T1a of the first reset transistor T1, the active layer T2a of the compensation transistor T2, and the conductorized portion that forms an integrated structure together with the active layer T1a of the first reset transistor T1 and the active layer T2a of the compensation transistor T2. Therefore, the active layer T1a of the first reset transistor T1 and the active layer T2a of the compensation transistor T2 are both made from the second semiconductor material (for example, IGZO). The conductorized portion is an electrically conductive material in which the second semiconductor material is conductorized. For example, the conductorized portion includes. For example, portions of the second electrically conductive structures located in the second type of via holes are in contact, through the second type of via holes, with structures exposed by the second type of the via holes for electrical connection. As a result, the second electrically conductive structure is formed, which is the electrode ET where the active layer T1a of the first reset transistor T1 shown in FIG. 3 is located. For the specific connection relationship of the second electrically conductive structure, please see the description of FIG. 3.

Then, as shown in FIG. 14C, the third gate insulating layer GI3, the third electrically conductive layer Gate3 and the second interlayer insulating layer ILD2 are formed in sequence, and the above-mentioned first type of via hole is formed through a single patterning process, for example, for example, the first type of via hole include a fifth via hole V5.

Then, after the first type of the via hole (e.g., the fifth via hole V5) is formed, a high temperature annealing process is performed on the display substrate to improve the characteristics of the LTPS TFT device (e.g., the first light emission control transistor T6). Then, the surface of the active layer Toa, which is made from the first semiconductor material and exposed by the fifth via hole V5, of the first light emission control transistor T6 is subjected to a contact resistance reduction treatment to reduce the contact resistance of the exposed surface, so that the exposed surface is enabled to become an ohmic contact with the second electrode Tod of the first light emission control transistor T6 which is subsequently in contact with the exposed surface through the fifth via hole V5. For example, the surface of the active layer Toa exposed by the fifth via V5 can be etched to remove the oxide layer on the surface of the active layer Toa exposed by the fifth via hole V5, thereby reducing the contact resistance of the exposed surface.

Then, as shown in FIG. 14D, an electrically conductive layer SD1 is formed, for example, by using a deposition method and a single patterning process, and the electrically conductive layer SD1 includes the second electrode T6d of the first light emission control transistor T6. The second electrode Tod of the first light emission control transistor T6 is electrically connected to the active layer T6a of the first light emission control transistor T6 through the fifth via hole V5.

It can be seen that in the manufacturing method of a display substrate provided by at least one embodiment of the present disclosure, after removing the oxide layer on the surface of the active layer Toa exposed by the fifth via hole V5, the electrically conductive layer SD1 can be immediately manufactured without a process for forming the second type of via hole therebetween. In this way, on the one hand, the ohmic contact between the active layer made from the first semiconductor material and the electrically conductive layer SD1 can be effectively improved; on the other hand, the formation of foreign matter such as impurity particles in the fifth via hole V5 can be effectively prevented, thereby preventing the influence of foreign matter such as impurity particles on the electrical connection between the active layer made from the first semiconductor material and the electrically conductive layer SD1, thereby improving the yield of the display substrate.

For example, in another method of manufacturing a display substrate shown in FIG. 3, after the second type of via hole is formed and before the second electrically conductive structure (i.e., the electrode ET where the active layer of the above-mentioned control transistor is located) is formed, a high-temperature annealing process is performed on the display substrate to prevent the high-temperature annealing process from affecting the performance of the second electrically conductive structure made from the second semiconductor material, thereby not affecting the performance of the control transistor.

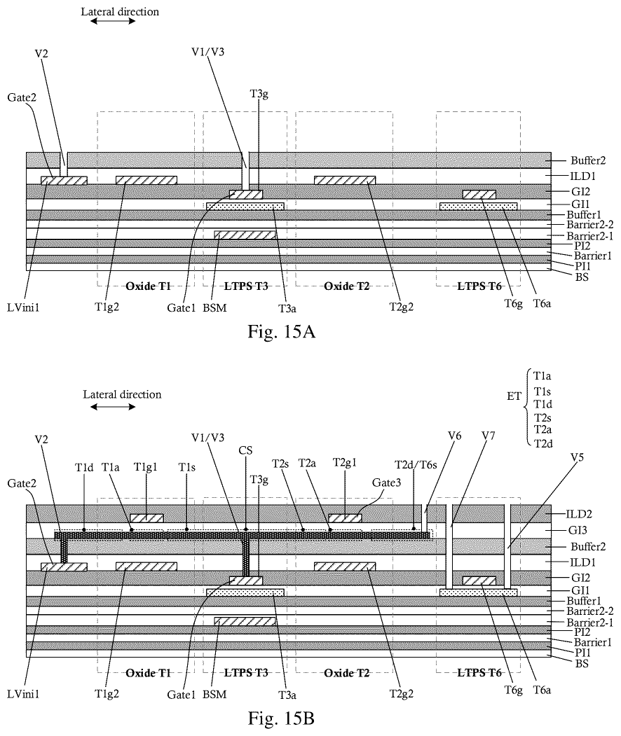

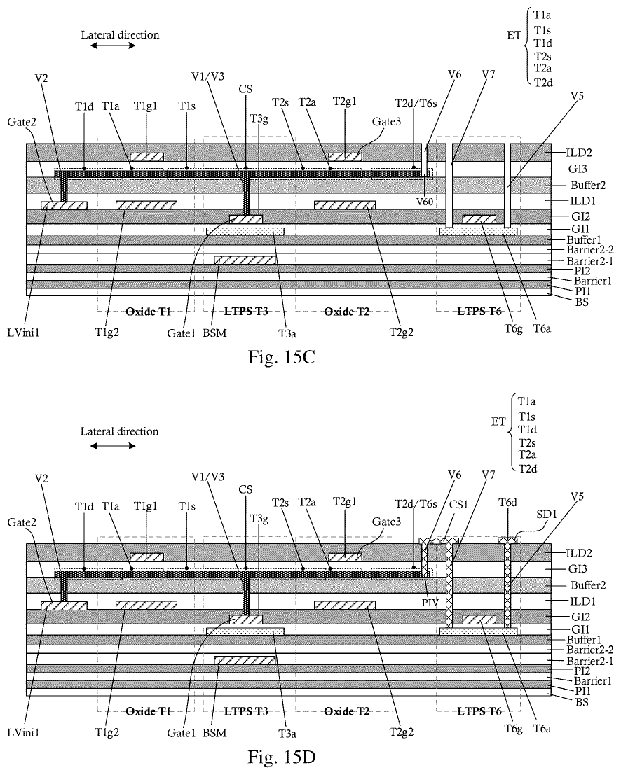

FIGS. 15A to 15D are schematic diagrams of a method for manufacturing a display substrate provided by an embodiment of the present disclosure. For example, FIGS. 15A to 15D show the method for manufacturing the display substrate shown in FIG. 6.

Referring to FIG. 15A, the difference from the step shown in FIG. 14A is that the above-mentioned second type of via hole is formed through a single patterning process, and the second type of via hole includes a first via hole V1 and a second via hole V2 (in this embodiment the second via hole V2 is also the third via hole V3), without forming the fourth via hole V4 in FIG. 14A.

Next, referring to FIG. 15B, a second semiconductor layer (not shown) is formed using the above-mentioned second semiconductor material, for example, a deposition method is used to form the second semiconductor layer, and a patterning process is performed on the second semiconductor layer to form a connection electrode pattern. Then, a portion of the connection electrode pattern is subjected to a conductorized treatment to form a second electrically conductive structure. The second electrically conductive structure is the electrode ET where the active layer T1a of the first reset transistor T1 shown in FIG. 6 is located. For the specific structure and connection relationship of the second electrically conductive structure, please refer to the description of FIG. 6. Then, the third gate insulating layer GI3, the third electrically conductive layer Gate3 and the second interlayer insulating layer ILD2 are formed in sequence, and the above-mentioned first type of via holes are formed through a single patterning process. For example, the first type of via holes include a fifth via hole V5 and a seventh via hole V7, the fifth via hole V5 and the seventh via hole V7 expose the surface of the active layer T1a of the first reset transistor T1 made from the first semiconductor material. Here, the first type of via hole further includes a sixth via hole V6 that exposes a conductorized portion of the second electrically conductive structure (i.e., the integrated electrode ET), and the sixth via V6 exposes an end of the electrode ET that is proximal to the first light emission control transistor T6 in the lateral direction, and the end of the electrode ET that is proximal to the first light emission control transistor T6 in the lateral direction is multi-used as the second electrode T2d of the compensation transistor T2.

Next, referring to FIG. 15C, a high-temperature annealing process is performed on the display substrate to improve the characteristics of the LTPS TFT device (such as the first light emission control transistor T6). Then, the surface of the active layer T6a made from the first semiconductor material of the first light emission control transistor T6 exposed by the fifth via hole V5 and the seventh via hole V7 is subjected to contact resistance reduction treatment. For example, the surface of the active layer Toa exposed by the fifth via hole V5 and the seventh via hole V7 may be etched to remove the oxide layer on the surface of the active layer T6a exposed by the fifth via hole V5 and the seventh via hole V7, thereby reducing the contact resistance of the exposed surface. After this etching process, the end of the electrode ET exposed by the sixth via hole V6 in FIG. 15B that is proximal to the first light emission control transistor T6 in the lateral direction is etched off, that is, the second electrode T2d of the compensation transistor T2 is etched off, so that the sixth via hole V6 penetrates the second electrode T2d of the compensation transistor T2 in a direction perpendicular to the main surface of the base substrate BS.

Next, referring to FIG. 15D, an electrically conductive layer SD1 is formed, for example, by using a deposition method and a single patterning process, and the electrically conductive layer SD1 includes the second electrode Tod of the first light emission control transistor T6 and the first connection structure CS1. The second electrode Tod of the first light emission control transistor T6 is electrically connected to the active layer Ta of the first light emission control transistor T6 through the fifth via hole V5. The first connection structure CS1 is electrically connected to the second electrode T2d of the compensation transistor T2 through the sixth via hole V6, and is electrically connected to the active layer T6a of the first light emission control transistor T6 through the seventh via hole V7.

Thus, the display substrate shown in FIG. 6 is formed. FIG. 6 uses a side overlapping manner to electrically connect the first connection structure CS1 to the second electrode T2d of the compensation transistor T2. In the manufacturing method of a display substrate provided by at least one embodiment of the present disclosure, after removing the oxide layer on the surface of the active layer Toa exposed by the fifth via hole V5 and the seventh via hole V7, the electrically conductive layer SD1 can be immediately formed without the processes for forming the second type of via hole therebetween. In this way, the technical effects of effectively improving the ohmic contact between the active layer made of the first semiconductor material and the electrically conductive layer SD1 and effectively preventing the formation of foreign matter such as impurity particles in the fifth via hole V5 can also be achieved.

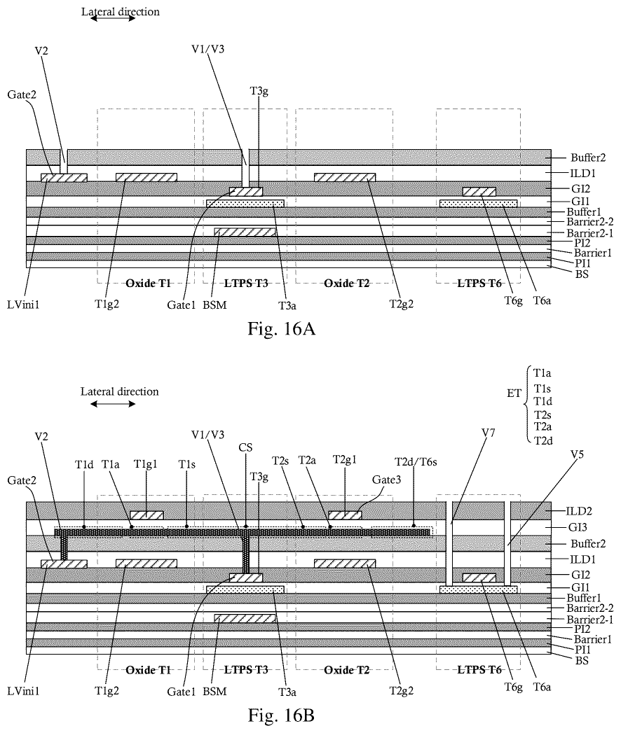

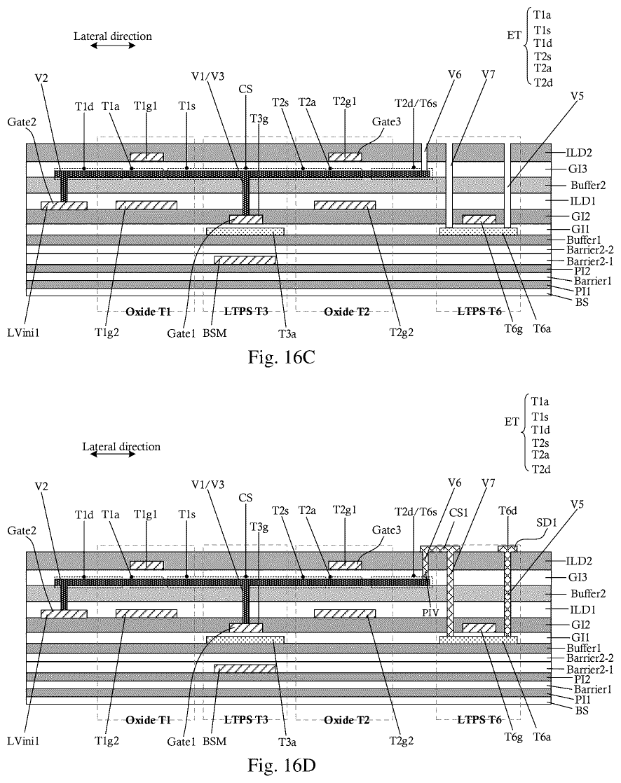

FIGS. 16A to 16D are schematic diagrams of a method for manufacturing a display substrate provided by an embodiment of the present disclosure. For example, FIGS. 16A to 16D show the method for manufacturing the display substrate shown in FIG. 7.

Referring to FIG. 16A, the steps are the same as those shown in FIG. 15A.

Next, referring to FIG. 16B, a second semiconductor layer (not shown) is formed by using the above-mentioned second semiconductor material, for example, a deposition method is used to form the second semiconductor layer, and a single patterning process is performed on the second semiconductor layer to form a connection electrode pattern. Then, a portion of the connection electrode pattern is subjected to a conductorized treatment to form a second electrically conductive structure. The second electrically conductive structure is the electrode ET where the active layer T1a of the first reset transistor T1 shown in FIG. 6 is located. For the specific structure and connection relationship of the second electrically conductive structure, please refer to the description of FIG. 6. Then, the third gate insulating layer GI3, the third electrically conductive layer Gate3 and the second interlayer insulating layer ILD2 are formed in sequence, and the above-mentioned first type of via holes are formed through a single patterning process. Different from the step shown in FIG. 15B, the first type of via hole here does not include the sixth via V6 that exposes the conductorized portion of the second electrically conductive structure (i.e., the integrated electrode ET), but includes the fifth via hole V5 and the seventh via hole V7. The fifth via hole V5 and the seventh via hole V7 expose the surface of the active layer T1a of the first reset transistor T1 made from the first semiconductor material.

Next, referring to FIG. 16C, a high-temperature annealing process is performed on the display substrate to improve the characteristics of the LTPS TFT device (such as the first light emission control transistor T6). Then, the surface of the active layer T6a, which is made from the first semiconductor material of the first light emission control transistor T6 and exposed by the fifth via hole V5 and the seventh via hole V7, is subjected to contact resistance reduction treatment. For example, the surface of the active layer T6a exposed by the fifth via hole V5 and the seventh via hole V7 may be etched to remove the oxide layer on the surface of the active layer T6a exposed by the fifth via hole V5 and the seventh via hole V7, thereby reducing the contact resistance of the exposed surface. After the etching process, the sixth via hole V6 is formed through a single patterning process, and the sixth via hole V6 exposes the upper surface of the end of the electrode ET proximal to the first light emission control transistor T6 in the lateral direction, and the end of the electrode ET proximal to the first light emission control transistor T6 in the lateral direction is multi-used as the second electrode T2d of the compensation transistor T2.

Next, referring to FIG. 16D, an electrically conductive layer SD1 is formed, for example, by using a deposition method and a single patterning process, and the electrically conductive layer SD1 includes the second electrode T6d of the first light emission control transistor T6 and the first connection structure CS1. The second electrode Tod of the first light emission control transistor T6 is electrically connected to the active layer Toa of the first light emission control transistor T6 through the fifth via hole V5. The first connection structure CS1 is electrically connected to the second electrode T2d of the compensation transistor T2 through the sixth via hole V6, and is electrically connected to the active layer T6a of the first light emission control transistor T6 through the seventh via hole V7.

Thus, the display substrate shown in FIG. 7 is formed. FIG. 7 uses a bottom overlapping method to electrically connect the first connection structure CS1 to the second electrode T2d of the compensation transistor T2. In the manufacturing method of a display substrate provided by at least one embodiment of the present disclosure, after removing the oxide layer on the surface of the active layer Toa exposed by the fifth via hole V5 and the seventh via hole V7, the electrically conductive layer SD1 can be immediately formed without a processes for forming the second type of via hole therebetween. In this way, the technical effects of effectively improving the ohmic contact between the active layer made of the first semiconductor material and the electrically conductive layer SD1 and effectively preventing the formation of foreign matter such as impurity particles in the fifth via hole V5 and the seventh via hole V7 can also be achieved.

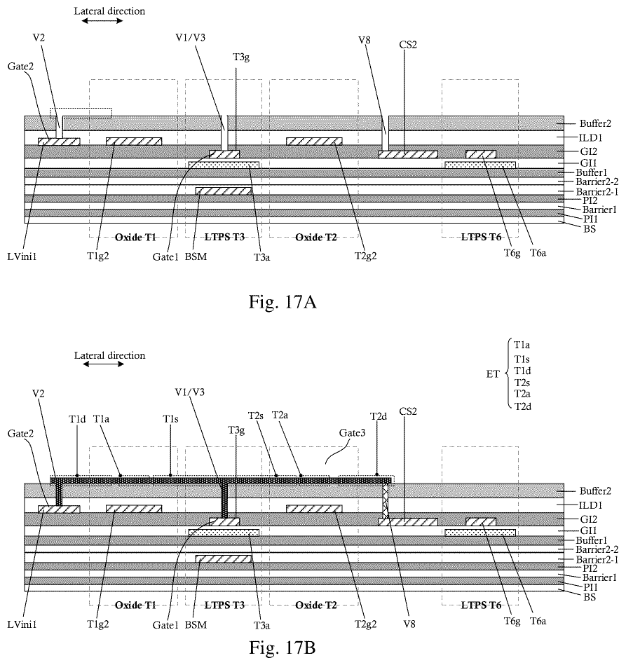

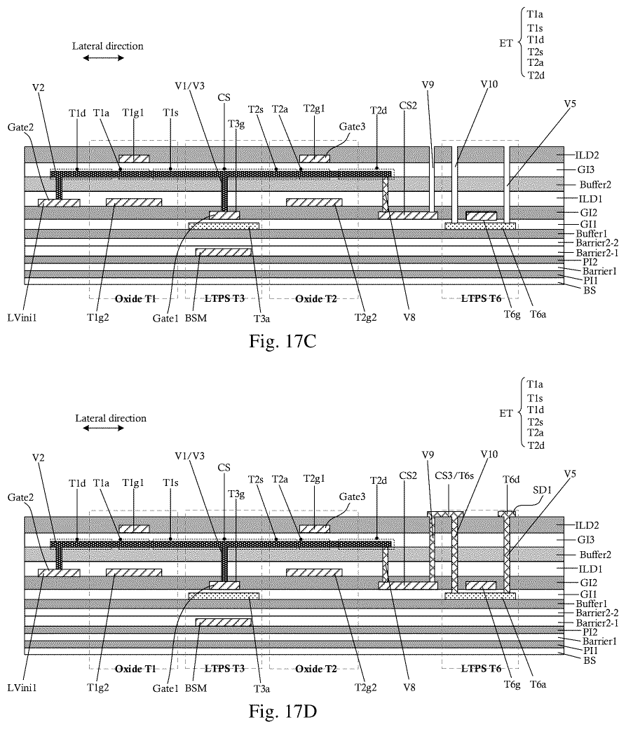

FIGS. 17A to 17D are schematic diagrams of a method for manufacturing a display substrate provided by an embodiment of the present disclosure. For example, FIGS. 17A to 17D show the method for manufacturing the display substrate shown in FIG. 8.

Referring to FIG. 17A, different from the step shown in FIG. 15A, the first metal layer Gate1 further includes a second connection structure CS2. The above-mentioned second type of via hole is formed through the same patterning process. Here, the second type of via hole includes the first via V1, the second via V2 (the second via V2 is also the third via V3 in this embodiment), and the eighth via V8 exposing the second connection structure CS2.

Next, referring to FIG. 17B, a second semiconductor layer (not shown) is formed by using the above-mentioned second semiconductor material, for example, a deposition method is used to form the second semiconductor layer, and a single patterning process is performed on the second semiconductor layer to form a connection electrode pattern. Then, a portion of the connection electrode pattern is subjected to a conductorized process to form the second electrically conductive structure. The second electrically conductive structure is the electrode ET where the active layer T1a of the first reset transistor T1 shown in FIG. 8 is located. For the specific structure and connection relationship of the second electrically conductive structure, please refer to the description of FIG. 8.

Then, referring to FIG. 17C, a third gate insulating layer GI3, a third electrically conductive layer Gate3 and a second interlayer insulating layer ILD2 are sequentially formed, and the above-mentioned first type of via holes are formed through a signal patterning process. Different from the step shown in FIG. 15B, the first type of via hole here does not include the sixth via hole V6 that exposes the conductorized portion of the second electrically conductive structure (i.e., the integrated electrode ET), but includes fifth and tenth via holes V5 and V10 exposing source and drain regions of the active layer Toa of the light-emitting control transistor T6 respectively and a ninth via V9 exposing the second connection structure CS2.

Next, a high-temperature annealing process is performed on the display substrate to improve the characteristics of the LTPS TFT device (such as the first light emission control transistor T6). Then, the surface of the active layer Toa made from the first semiconductor material of the first light emission control transistor T6 exposed by the fifth via hole V5 and the seventh via hole V7 is subjected to contact resistance reduction treatment. For example, the surface of the active layer Toa exposed by the fifth via hole V5 and the tenth via hole V10 may be etched to remove the oxide layer on the surface of the active layer Toa exposed by the fifth via hole V5 and the seventh via hole V7, thereby reducing the contact resistance of the exposed surface.

Next, referring to FIG. 17D, an electrically conductive layer SD1 is formed, for example, by using a deposition method and a single patterning process, and the electrically conductive layer SD1 includes a first connection structure CS1, a second connection structure CS2 and a third connection structure CS3. The second electrode T6d of the first light emission control transistor T6 is electrically connected to the active layer Toa of the first light emission control transistor T6 through the fifth via hole V5. The second electrode T2d of the compensation transistor T2 is electrically connected to the second connection structure CS2 through the eighth via hole V8, the third connection structure CS3 is electrically connected to the second connection structure CS2 through the ninth via hole V9, and the third connection structure CS3 is electrically connected to the active layer T6a of the first light emission control transistor T6 through the tenth via hole V10, so that the third connection structure CS3 serves as the first electrode Tos of the first light emission control transistor T6.

Thus, the display substrate shown in FIG. 8 is formed. In the manufacturing method of a display substrate provided by at least one embodiment of the present disclosure, after removing the oxide layer on the surface of the active layer T6a exposed by the fifth via hole V5 and the tenth via hole V10, the electrically conductive layer SD1 can be immediately formed without the processes for forming the second type of via hole therebetween. In this way, the technical effects of effectively improving the ohmic contact between the active layer made of the first semiconductor material and the electrically conductive layer SD1 and effectively preventing the formation of foreign matter such as impurity particles in the fifth via hole V5 and the tenth via hole V10 can also be achieved.

Regarding the manufacturing methods of the display substrate shown in FIGS. 9 to 12, on the basis of the manufacturing methods of the display substrate shown in FIGS. 3, 6, 7, and 8 respectively, the second metal layer Gate2 is formed through a single patterning process. During the process, the patterning pattern may be changed so as not to form the second gate electrode T1g2 of the first reset transistor T1 and the second gate electrode T2g2 of the compensation transistor T2. For other method steps, please refer to the manufacturing methods of the display substrate shown in FIGS. 3, 6, 7, and 8 respectively. The technical effects of the manufacturing methods of the display substrate shown in FIGS. 3, 6, 7, and 8 can also be achieved, moreover, the step of removing the above-mentioned second gate simplifies the design of the mask and simplifies the process.

The following points need to be explained:

(1) The drawings of the embodiments of the present disclosure only relate to the structures related to the embodiments of the present disclosure, and other structures may refer to common designs.

(2) Without conflict, the embodiments of the present disclosure and the features in the embodiments can be combined with each other to obtain new embodiments.

The above descriptions are only exemplary embodiments of the present invention and are not intended to limit the scope of protection of the present invention, which is determined by the appended claims.

1. A display substrate, comprising a sub-pixel, wherein the sub-pixel comprises a pixel circuit, the pixel circuit comprises a light-emitting device and a driving transistor, and the driving transistor is configured to control a driving current flowing through the light-emitting device according to a data signal;
the pixel circuit further comprises a control transistor, a first electrode of the control transistor is electrically connected to a gate electrode of the driving transistor;
a material of an active layer of the driving transistor is a first semiconductor material and a material of an active layer of the control transistor is a second semiconductor material, the first semiconductor material is different from the second semiconductor material;
an electrode where the active layer of the control transistor is located is directly electrically connected to the gate electrode of the driving transistor and the first electrode of the control transistor.

2. The display substrate according to claim 1, wherein the active layer of the driving transistor and the active layer of the control transistor are arranged in different layers, and the gate electrode of the driving transistor is located between the active layer of the driving transistor and the electrode on which the active layer of the control transistor is located.

3. The display substrate according to claim 2, wherein the display substrate comprises a base substrate, the driving transistor is disposed on a main surface of the base substrate;
the active layer of the driving transistor is located on a side of the active layer of the control transistor proximal to the base substrate.

4. The display substrate according to claim 1, wherein the pixel circuit comprises: a first reset transistor configured to write a first reset signal to the gate electrode of the driving transistor under a control of a first reset control signal;
the control transistor comprises the first reset transistor, and an electrode where an active layer of the first reset transistor is located is directly electrically connected to the gate electrode of the driving transistor and a first electrode of the first reset transistor.

5. The display substrate according to claim 4, wherein the electrode where the active layer of the first reset transistor is located comprises the active layer of the first reset transistor and the first electrode of the first reset transistor, a material of the first electrode of the first reset transistor is a conductorized material of the second semiconductor material, and the active layer of the first reset transistor and the first electrode of the first reset transistor are arranged in a same layer and constitute an integrated structure;
the gate electrode of the driving transistor is arranged in a different layer from the electrode where the active layer of the first reset transistor is located, and the first electrode of the first reset transistor is in contact, through a first via hole exposing the gate electrode of the driving transistor, with the gate electrode of the driving transistor to directly electrically connect the gate electrode of the driving transistor.

6. The display substrate according to claim 5, wherein the electrode where the active layer of the first reset transistor is located further comprises a second electrode of the first reset transistor, and a material of the second electrode of the first reset transistor is a conductorized material of the second semiconductor material;
the pixel circuit further comprises a first reset signal line disposed in a different layer from the second electrode of the first reset transistor, and the second electrode of the first reset transistor is in contact, through a second via hole exposing the first reset signal line, with the first reset signal line to directly electrically connect the first reset signal line.

7. The display substrate according to claim 1, wherein the pixel circuit further comprises: a compensation transistor configured to compensate a signal applied to a gate electrode of the driving transistor in response to a compensation scan signal and the data signal;
the control transistor further comprises the compensation transistor, and an electrode where an active layer of the compensation transistor is located is directly electrically connected to the gate electrode of the driving transistor and a first electrode of the compensation transistor.

8. The display substrate according to claim 7, wherein the electrode where the active layer of the compensation transistor is located further comprises the first electrode of the compensation transistor, and materials of the active layer of the compensation transistor and the first electrode of the compensation transistor are both a conductorized material of the second semiconductor material, and the active layer of the compensation transistor and the first electrode of the compensation transistor are arranged in a same layer and constitute an integrated structure;
the gate electrode of the driving transistor and the electrode where the active layer of the compensation transistor is located are arranged in different layers, and the first electrode of the compensation transistor is in contact, through a third via hole exposing the gate electrode of the driving transistor, with the gate electrode of the driving transistor to directly electrically connect the gate electrode of the driving transistor.

9. The display substrate according to claim 8, wherein the control transistor comprises a first reset transistor, an electrode where an active layer of the first reset transistor is located comprises the active layer of the first reset transistor and a first electrode of the first reset transistor, a material of the first electrode of the first reset transistor is the conductorized material of the second semiconductor material, the active layer of the first reset transistor and the first electrode of the first reset transistor are arranged in a same layer and constitute an integrated structure; the gate electrode of the driving transistor and the electrode where the active layer of the first reset transistor are located are arranged in different layers, and the first electrode of the first reset transistor is in contact with the gate electrode of the driving transistor through a first via that exposes the gate electrode of the driving transistor to directly electrically connect the gate electrode of the driving transistor,
the electrode where the active layer of the compensation transistor and the electrode where the active layer of the first reset transistor is located are arranged in a same layer as and constitute an integrated structure, the first electrode of the first reset transistor and the first electrode of the compensation transistor are integrated, and the first via hole and the second via hole are the same via hole;
a material of the active layer of the compensation transistor is the second semiconductor material, a material of the first electrode of the compensation transistor is a conductorized material of the second semiconductor material; the first electrode of the compensation transistor, the first electrode of the compensation transistor and the active layer of the compensation transistor are connected in sequence, arranged in a same layer and constitute an integrated structure.

10. The display substrate according to claim 7, wherein the pixel circuit further comprises a first light emission control transistor configured to enable the driving current to be applied to the light emitting device under a control of a first light emission control signal;
a material of an active layer of the first light emission control transistor is the first semiconductor material, and the active layer of the first light emission control transistor is arranged in a different layer from an active layer of the control transistor;
the electrode where the active layer of the compensation transistor is located further comprises a connection portion, a material of the connection portion is a conductorized material of the second semiconductor material, and the connection portion and the active layer of the compensation transistor are arranged in a same layer and constitute an integrated structure;
the connection portion is in contact with the active layer of the first light emission control transistor through a fourth via hole exposing the active layer of the first light emission control transistor to electrically connect the active layer of the first light emission control transistor, and the connection portion serves as the first electrode of the first light emission control transistor and the second electrode of the compensation transistor.

11. The display substrate according to claim 10, wherein the active layer of the first emission control transistor and the active layer of the driving transistor are disposed in the same layer, and/or,
the gate electrode of the driving transistor and a gate electrode of the first light emission control transistor are disposed in a same layer.

12. The display substrate according to claim 1, wherein the pixel circuit further comprises a first emission control transistor configured to enable the driving current to be applied to the light emitting device under a control of a first emission control signal;
a material of an active layer of the first light emission control transistor is the first semiconductor material, and the active layer of the first light emission control transistor is arranged in a different layer from the active layer of the control transistor;
the electrode where the active layer of the control transistor is located is arranged in a different layer from a second electrode of the first light emission control transistor, the electrode where the active layer of the control transistor is located is in contact with the active layer of the first light emission control transistor through a fourth via hole exposing the active layer of the first light emission control transistor, and the second electrode of the first light emission control transistor is in contact with the active layer of the first light emission control transistor through a fifth via hole exposing the active layer of the first light emission control transistor.

13. The display substrate according to claim 12, wherein the display substrate comprises a base substrate, the driving transistor being disposed on a main surface of the base substrate;
the second electrode of the first light emission control transistor is located on a side of the electrode where the active layer of the control transistor is located distal to the base substrate.

14. The display substrate according to claim 12, wherein the control transistor comprises a first reset transistor, an electrode where an active layer of the first reset transistor is located further comprises a second electrode of the first reset transistor, a material of the second electrode of the first reset transistor is a conductorized material of the second semiconductor material, the pixel circuit further comprises a first reset signal line provided in a different layer from the second electrode of the first reset transistor, and the second electrode of the first reset transistor is electrically connected to the first reset signal line through a second via hole exposing the first reset signal line,
the first reset signal line is disposed in a different layer from the second electrode of the first light emission control transistor.

15. The display substrate according to claim 14, wherein the first reset signal line and the gate electrode of the driving transistor are located between the gate electrode of the driving transistor and the electrode where the active layer of the control transistor is located;
the first reset signal line and the gate electrode of the driving transistor are arranged in different layers or in a same layer.

16. The display substrate according to claim 15, wherein the control transistor is a single-gate type transistor, a gate electrode of the control transistor is located on a side of the active layer of the control transistor distal to the active layer of the driving transistor; or,
the control transistor is a double-gate type transistor, a first gate electrode of the control transistor is located on a side of the active layer of the control transistor distal to the active layer of the driving transistor, and a second gate electrode of the control transistor is located between the active layer of the control transistor and the active layer of the driving transistor, and the second gate electrode of the control transistor and the first reset signal line are arranged in a same layer or in different layers.

17-18. (canceled)

19. The display substrate according to claim 7, wherein the pixel circuit further comprises a first light emission control transistor configured to enable the driving current to be applied to the light emitting device under a control of a first light emission control signal;
a material of an active layer of the first light emission control transistor is the first semiconductor material, and the active layer of the first light emission control transistor is arranged in a different layer from the active layer of the control transistor;
the electrode where the active layer of the compensation transistor is located further comprises a second electrode of the compensation transistor, a material of the second electrode of the compensation transistor is a conductorized material of the second semiconductor material, and the second electrode of the compensation transistor and the active layer of the compensation transistor are arranged in a same layer and constitute an integrated structure;
the pixel circuit comprises a first connection structure, and the first connection structure, the second electrode of the compensation transistor, and the electrode where the active layer of the control transistor are all arranged in different layers from each other;
the first connection structure is electrically connected to the second electrode of the compensation transistor through a sixth via hole, and is electrically connected to the active layer of the first light emission control transistor through a seventh via hole.

20. (canceled)

21. The display substrate according to claim 7, wherein the pixel circuit further comprises a first light emission control transistor configured to enable the driving current to be applied to the light emitting device under a control of a first light emission control signal;
a material of an active layer of the first light emission control transistor is the first semiconductor material, and the active layer of the first light emission control transistor is arranged in a different layer from the active layer of the control transistor;
an electrode where the active layer of the compensation transistor is located further comprises a second electrode of the compensation transistor, a material of the second electrode of the compensation transistor is a conductorized material of the second semiconductor material, and the connection portion and the active layer of the compensation transistor are arranged in a same layer as and constitute an integrated structure;
the pixel circuit further comprises a second connection structure and a third connection structure, and the second electrode of the compensation transistor, the second connection structure, the third connection structure and the active layer of the first light emission control transistor are all arranged in different layers from each other;
the second electrode of the compensation transistor is electrically connected to the second connection structure through an eighth via hole, the third connection structure is electrically connected to the second connection structure through a ninth via hole, and the third connection structure is electrically connected to the active layer of the first light emission control transistor through a tenth via hole.

22-23. (canceled)

24. A display apparatus, comprising a display substrate, the display substrate comprising a sub-pixel, wherein the sub-pixel comprises a pixel circuit, the pixel circuit comprises a light-emitting device and a driving transistor, and the driving transistor is configured to control a driving current flowing through the light-emitting device according to a data signal;
the pixel circuit further comprises a control transistor, a first electrode of the control transistor is electrically connected to a gate electrode of the driving transistor;
a material of an active layer of the driving transistor is a first semiconductor material and a material of an active layer of the control transistor is a second semiconductor material, the first semiconductor material is different from the second semiconductor material;
an electrode where the active layer of the control transistor is located is directly electrically connected to the gate electrode of the driving transistor and the first electrode of the control transistor.

25. A method for manufacturing a display substrate, comprising:
forming a sub-pixel, comprising forming a pixel circuit, wherein the forming a pixel circuit comprises: forming a light emitting device and a driving transistor configured to control a magnitude of a driving current flowing through the light emitting device according to a data signal;
the forming a pixel circuit further comprises: forming a control transistor, wherein a first electrode of the control transistor is electrically connected to a gate electrode of the driving transistor; a material of an active layer of the driving transistor is a first semiconductor material and a material of an active layer of the control transistor is a second semiconductor material, the first semiconductor material is different from the second semiconductor material; an electrode where the active layer of the control transistor is located is directly electrically connected to the gate electrode of the driving transistor and the first electrode of the control transistor.

26-28. (canceled)
